(19) United States
(12) Patent Application Publication
(10) Pub. No.: US 2024/0431159 A1
(43) Pub. Date: Dec. 26, 2024

(54) ARRAY SUBSTRATE, DISPLAY PANEL AND DISPLAY APPARATUS

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Shilong WANG, Beijing (CN); Zhiliang JIANG, Beijing (CN); Ziyang YU, Beijing (CN)

(21) Appl. No.: 18/248,622

(22) PCT Filed: Mar. 25, 2022
(86) PCT No.: PCT/CN2022/083195

§ 371 Date: Sep. 10, 2024

(51) Int. Cl. H10K 59/131

(52) U.S. Cl. CPC H10K 59/131

(57) ABSTRACT

An array substrate includes a substrate, first power supply signal lines, data lines and fan-out lines. The fan-out lines each include a first sub-line and a second sub-line; an end of the second sub-line is electrically connected to the first sub-line, another end of the second sub-line is electrically connected to a single data line, and the second sub-line is insulated from remaining data lines of the data lines. The first sub-line and main structures of the data lines are disposed in a same layer. An orthographic projection, on the substrate, of a first sub-line passing through a column of sub-pixel regions is substantially located between an orthographic projection, on the substrate, of a first power supply signal line passing through the column of sub-pixel regions and an orthographic projection, on the substrate, of a data line passing through the column of sub-pixel regions.

### CROSS-REFERENCE TO RELATED APPLICATION

This application is a national phase entry under 35 USC 371 of International Patent Application No. PCT/CN2022/083195, filed on Mar. 25, 2022, which is incorporated herein by reference in its entirety.

### TECHNICAL FIELD

The present disclosure relates to the field of display technologies, and in particular, to an array substrate, a display panel and a display apparatus.

### BACKGROUND

At present, organic light-emitting diode (OLED) display apparatuses have been widely used due to their characteristics of self-luminescence, quick response, wide viewing angle, being capable of being manufactured on flexible substrates and the like. The OLED display apparatuses each include a plurality of sub-pixels; each sub-pixel includes a pixel driving circuit and a light-emitting device, and the pixel driving circuit drives the light-emitting device to emit light, so as to achieve display.

### SUMMARY

In an aspect, an array substrate is provided. The array substrate includes a substrate, a plurality of first power supply signal lines, a plurality of data lines and a plurality of fan-out lines. The substrate has a display area and a peripheral area. The plurality of first power supply signal lines are located on a first side of the substrate and located in the display area; the plurality of first power supply signal lines each extend in a first direction and are sequentially arranged in a second direction; the second direction intersects the first direction, and the second direction and the first direction are both parallel to the substrate. The plurality of data lines are located on the first side of the substrate and located in the display area; the plurality of data lines each extend in the first direction and are sequentially arranged in the second direction; a data line is adjacent to a first power supply signal line. The plurality of fan-out lines are located on the first side of the substrate; the plurality of fan-out lines each include a first sub-line and a second sub-line; the first sub-line extends in the first direction and extends from the peripheral area to the display area; the second sub-line extends in the second direction and is located in the display area; an end of the second sub-line is electrically connected to the first sub-line, another end of the second sub-line is electrically connected to a single data line of the plurality of data lines, and the second sub-line is insulated from remaining data lines of the plurality of data lines.

Main structures of the plurality of data lines are located on a side of the first power supply signal lines away from the substrate, and the first sub-line and the main structures of the plurality of data lines are disposed in a same layer. The display area has sub-pixel regions in a plurality of rows and a plurality of columns; an orthographic projection, on the substrate, of a first sub-line passing through a column of sub-pixel regions is substantially located between an orthographic projection, on the substrate, of a first power supply signal line passing through the column of sub-pixel regions and an orthographic projection, on the substrate, of a data line passing through the column of sub-pixel regions.

In some embodiments, the peripheral area includes a lead-out region located on a side of the display area; the first sub-line extends from the lead-out region to the display area, and a length of at least one first sub-line is not greater than half a dimension of the display area in the first direction.

In some embodiments, a direction from a center line, in the second direction, of the display area to any side of the display area in the second direction is a first setting direction; lengths of portions, located in the display area, of first sub-lines of all first sub-lines included in the plurality of fan-out lines sequentially decrease in the first setting direction.

In some embodiments, the main structures of the plurality of data lines each include a plurality of main lines; at least part of the plurality of data lines each further include at least one jumper wire, and the at least one jumper wire and the first power supply signal lines are disposed in another same layer; in a same data line, at least one jumper wire and main lines are alternately electrically connected to one other through via holes; the second sub-line and the plurality of main lines are arranged in the same layer, and each of at least one second sub-line crosses a jumper wire of at least one data line. In some embodiments, the array substrate further includes an active film layer disposed between the at least one jumper wire and the substrate; a jumper wire has an extension portion, and an end of the extension portion is connected to the active film layer through a via hole.

In some embodiments, a minimum closed graphic region where all second sub-lines, located on a same side of a center line of the display area in the second direction, are located is a first wiring region; at least a portion, located within the first wiring region, of each of data lines passing through the first wiring region is provided with a jumper wire.

In some embodiments, a direction from a center line, in the second direction, of the display area to any side of the display area in the second direction is a first setting direction; numbers of jumper wires respectively included in data lines firstly increase and then decrease in the first setting direction.

In some embodiments, of all the data lines passing through the first wiring region, a data line of which a portion located within the first wiring region has a greatest number of jumper wires is a first-type data line, and data lines other than the first-type data line are second-type data lines.

A portion, located outside the first wiring region, of each of all the second-type data lines is provided with a jumper wire; a number of jumper wires included in each of all the second-type data lines is equal to a number of jumper wires included in the first-type data line.

In some embodiments, an end of the first sub-line connected to the second sub-line is a first end, and another end of the first sub-line is a second end; a direction from the second end to the first end is a second setting direction; of each of all the second-type data lines, the jumper wire located within the first wiring region and the jumper wire located outside the first wiring region are arranged in the second setting direction.

In some embodiments, a portion, located outside the first wiring region, of each of all the data lines passing through the first wiring region is provided with a jumper wire; a number of jumper wires included in each data line is equal; jumper wires included in all the data lines passing through the first wiring region are arranged in rows in the first direction.

In some embodiments, the array substrate includes a first source-drain metal layer located on the first side of the substrate and a second source-drain metal layer located on a side of the first source-drain metal layer away from the substrate. The first power supply signal lines and the at least one jumper wire are located in the first source-drain metal layer, and the first sub-line, the second sub-line and the plurality of main lines are located in the second source-drain metal layer.

In some embodiments, the second sub-line is located in a layer different from the layer in which the main structures of the plurality of data lines are located.

In some embodiments, the array substrate includes at least one gate metal layer located on the first side of the substrate, a first source-drain metal layer located on a side of the at least one gate metal layer away from the substrate and a second source-drain metal layer located on a side of the first source-drain metal layer away from the substrate. The second sub-line is disposed in any gate metal layer, the first power supply signal lines are disposed in the first source-drain metal layer, and the first sub-line and the main structures of the plurality of data lines are disposed in the second source-drain metal layer.

In some embodiments, the array substrate includes a plurality of first initial signal lines located on the first side of the substrate and located in the display area. The plurality of first initial signal lines each extend in the second direction; the plurality of first initial signal lines are located in a layer different from a layer in which the second sub-line is located; an orthographic projection, on the substrate, of a first initial signal line corresponding to a row of sub-pixel regions at least partially overlaps with an orthographic projection, on the substrate, of a second sub-line corresponding to the row of sub-pixel regions.

In some embodiments, the array substrate further includes a plurality of second initial signal lines located on the first side of the substrate and located in the display area. The plurality of second initial signal lines each extend in the first direction. The plurality of second initial signal lines are located in a layer different from the layer in which the plurality of first initial signal lines are located, and the plurality of second initial signal lines are electrically connected to the plurality of first initial signal lines through another via holes; an orthographic projection, on the substrate, of another first sub-line corresponding to the column of sub-pixel regions at least partially overlaps with an orthographic projection, on the substrate, of a second initial signal line corresponding to the column of sub-pixel regions.

In some embodiments, the second initial signal lines and the at least one jumper wire are located in the another same layer, and a second initial signal line is located between a jumper wire and a first power supply signal line; the second initial signal line has an avoidance portion bent towards a side where the first power supply signal line is located, and at least a portion of the jumper wire is located within an avoidance space defined by the avoidance portion.

In another aspect, an array substrate is provided. The array substrate includes a substrate, a plurality of first power supply signal lines, a plurality of data lines and a plurality of fan-out lines. The substrate has a display area and a peripheral area. The plurality of first power supply signal lines are located on a first side of the substrate and located in the display area; the plurality of first power supply signal lines each extend in a first direction and are sequentially arranged in a second direction; the second direction intersects the first direction, and the second direction and the first direction are both parallel to the substrate. The plurality of data lines are located on the first side of the substrate and located in the display area; the plurality of data lines each extend in the first direction and are sequentially arranged in the second direction; a data line is adjacent to a first power supply signal line. The plurality of fan-out lines are located on the first side of the substrate. A fan-out line includes a first sub-line and a second sub-line; the first sub-line extends in the first direction and extends from the peripheral area to the display area; the second sub-line extends in the second direction and is located in the display area; an end of the second sub-line is electrically connected to the first sub-line, another end of the second sub-line is electrically connected to a single data line of the plurality of data lines, and the second sub-line is insulated from remaining data lines of the plurality of data lines.

Main structures of the data lines are located on a side of the first power supply signal lines away from the substrate, and the first sub-line and the main structures of the data lines are disposed in a same layer.

The array substrate has pixel driving circuits in a plurality of rows and a plurality of columns; an orthographic projection, on the substrate, of the first sub-line passing through a column of pixel driving circuits is located between an orthographic projection, on the substrate, of a first power supply signal line passing through the column of pixel driving circuits and an orthographic projection, on the substrate, of a data line passing through the column of pixel driving circuits.

In yet another aspect, a display panel is provided. The display panel includes the array substrate as described in any one of the above embodiments, a light-emitting device layer and an encapsulation layer. The light-emitting device layer is located on a side of the array substrate away from the substrate; the encapsulation layer is located on a side of the light-emitting device layer away from the array substrate.

In yet another aspect, a display apparatus is provided. The display apparatus includes the display panel as described in any one of the above embodiments, a flexible circuit board and a main control circuit board. The peripheral area of the display panel includes a lead-out region and a bonding region that are located on a side of the display area, and the bonding region is located on a side of the lead-out region away from the display area. An end of the flexible circuit board is bonded in the bonding region; the main control circuit board is electrically connected to another end of the flexible circuit board.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art can obtain other drawings according to these drawings. In addition, the accompanying drawings in the following description may be regarded as schematic diagrams, and are not limitations on actual sizes of products, actual processes of methods and actual timings of signals involved in the embodiments of the present disclosure.

FIG. 1A is a structural diagram of a display apparatus, in accordance with some embodiments;

FIG. 1B is a structural diagram of a display panel, in accordance with some embodiments;

FIG. 1C is a structural diagram of another display panel, in accordance with some embodiments;

FIG. 1D is a structural diagram of yet another display panel, in accordance with some embodiments;

FIG. 1E is a structural diagram of yet another display panel, in accordance with some embodiments;

FIG. 1F is a structural diagram of yet another display panel, in accordance with some implementations;

FIG. 1G is a structural diagram of yet another display panel, in accordance with some implementations;

FIG. 2A is a structural diagram of an array substrate, in accordance with some embodiments;

FIG. 2B is a structural diagram of another array substrate, in accordance with some embodiments;

FIG. 3A is a structural diagram of yet another array substrate, in accordance with some embodiments;

FIG. 3B is a structural diagram of yet another array substrate, in accordance with some embodiments;

FIG. 4A is a structural diagram of yet another array substrate, in accordance with some embodiments;

FIG. 4B is a structural diagram of yet another array substrate, in accordance with some embodiments;

FIG. 5 is a structural diagram of yet another array substrate, in accordance with some embodiments;

FIG. 6 is a structural diagram of yet another array substrate, in accordance with some embodiments;

FIG. 7 is a structural diagram of yet another array substrate, in accordance with some embodiments;

FIG. 8 is a structural diagram of yet another array substrate, in accordance with some embodiments;

FIG. 9 is a structural diagram of yet another array substrate, in accordance with some embodiments;

FIG. 10 is a structural diagram of yet another array substrate, in accordance with some embodiments;

FIG. 11A is a structural diagram of yet another array substrate, in accordance with some embodiments;

FIG. 11B is a structural diagram of yet another array substrate, in accordance with some embodiments;

FIG. 12 is a structural diagram of a pixel driving circuit, in accordance with some embodiments;

FIG. 13A is a structural diagram of yet another array substrate, in accordance with some embodiments;

FIG. 13B is a structural diagram of yet another array substrate, in accordance with some embodiments;

FIG. 14 is a structural diagram of yet another array substrate, in accordance with some embodiments;

FIG. 15 is a structural diagram of yet another array substrate, in accordance with some embodiments;

FIG. 16 is a structural diagram of yet another array substrate, in accordance with some embodiments;

FIG. 17 is a structural diagram of yet another array substrate, in accordance with some embodiments;

FIG. 18A is a structural diagram of yet another array substrate, in accordance with some embodiments;

FIG. 18B is a structural diagram of yet another array substrate, in accordance with some embodiments;

FIG. 19A is a structural diagram of yet another array substrate, in accordance with some embodiments;

FIG. 19B is a structural diagram of yet another array substrate, in accordance with some embodiments;

FIG. 19C is a structural diagram of yet another array substrate, in accordance with some embodiments;

FIG. 19D is a structural diagram of yet another array substrate, in accordance with some embodiments;

FIG. 20A is a structural diagram of yet another array substrate, in accordance with some embodiments;

FIG. 20B is a structural diagram of yet another array substrate, in accordance with some embodiments;

FIG. 20C is a structural diagram of yet another array substrate, in accordance with some embodiments;

FIG. 21 is a structural diagram of yet another array substrate, in accordance with some embodiments;

FIG. 22 is a structural diagram of yet another display panel, in accordance with some embodiments;

FIG. 23 shows a structure of yet another display panel, in accordance with some embodiments; and

FIG. 24 is a structural diagram of yet another array substrate, in accordance with some embodiments.

### DETAILED DESCRIPTION

Technical solutions in some embodiments of the present disclosure will be described clearly and completely below with reference to the accompanying drawings. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a plurality of” or “the plurality of” means two or more unless otherwise specified.

In the description of some embodiments, the terms such as “connected” and derivatives thereof may be used. For example, the term “connected” may be used in the description of some embodiments to indicate that two or more components are in direct physical or electrical contact with each other.

In the description of some embodiments, the term “corresponding” may be used. For example, in the description of some embodiments, the term “corresponding” may be used to describe that a line corresponds to a region, so as to indicate that an orthographic projection of the line on a plane overlaps with an orthographic projection of the region on the plane. For another example, in the description of some embodiments, the term “corresponding” may be used to describe that a line corresponds to another line, so as to indicate that the line is electrically connected to the another line.

In the description of some embodiments, the term “crossing” may be used. For example, in the description of some embodiments, the term “crossing” may be used to describe that a line crosses another line, so as to indicate that an orthographic projection of the line on a plane intersects an orthographic projection of the another line on the plane.

In the description of some embodiments, the term “passing through” may be used. For example, in the description of some embodiments, the term “passing through” may be used to describe that a line passes through a region, so as to indicate that an orthographic projection of the line on a plane partially or completely overlaps with an orthographic projection of the region on the plane.

The phase “based on” as used herein is meant to be open and inclusive, since a process, a step, a calculation or other action that is “based on” one or more of stated conditions or values may, in practice, be based on additional conditions or values beyond those stated.

As used herein, the term “substantially” includes a stated value and an average value within an acceptable range of deviation of a particular value. The acceptable range of deviation is determined by a person of ordinary skill in the art in view of measurement in question and errors associated with measurement of a particular quantity (i.e., limitations of a measurement system).

As used herein, the term “perpendicular” includes a stated condition and a condition similar to the stated condition, a range of the similar condition is within an acceptable range of deviation, and the acceptable range of deviation is determined by a person of ordinary skill in the art, considering measurement in question and errors associated with measurement of a particular quantity (i.e., limitations of a measurement system). The term “perpendicular” includes absolute perpendicularity and approximate perpendicularity, and an acceptable range of deviation of the approximate perpendicularity may be, for example, a deviation within 5°.

It will be understood that, in a case where a layer or an element is referred to as being on another layer or a substrate, it may be that the layer or the element is directly on the another layer or the substrate, or there may be a middle layer between the layer or the element and the another layer or the substrate.

Exemplary embodiments are described herein with reference to sectional views and/or plan views as idealized exemplary drawings. In the accompanying drawings, thicknesses of layers and sizes of regions are enlarged for clarity. Thus, variations in shape relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of regions in a device, and are not intended to limit the scope of the exemplary embodiments.

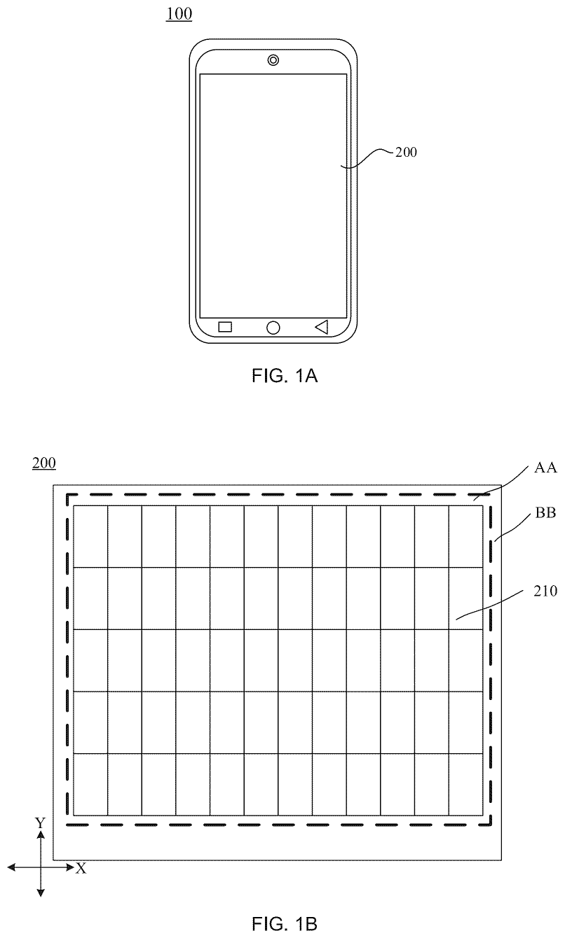

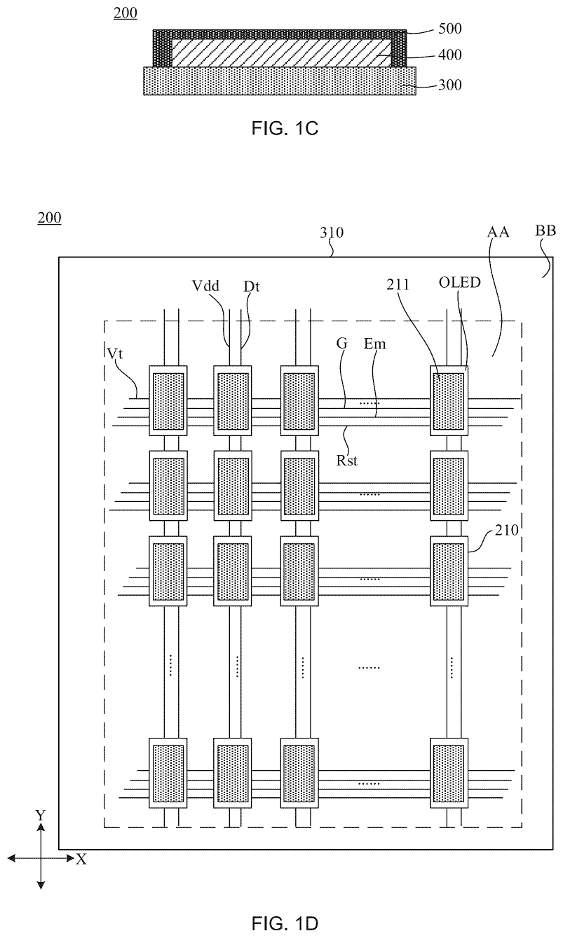

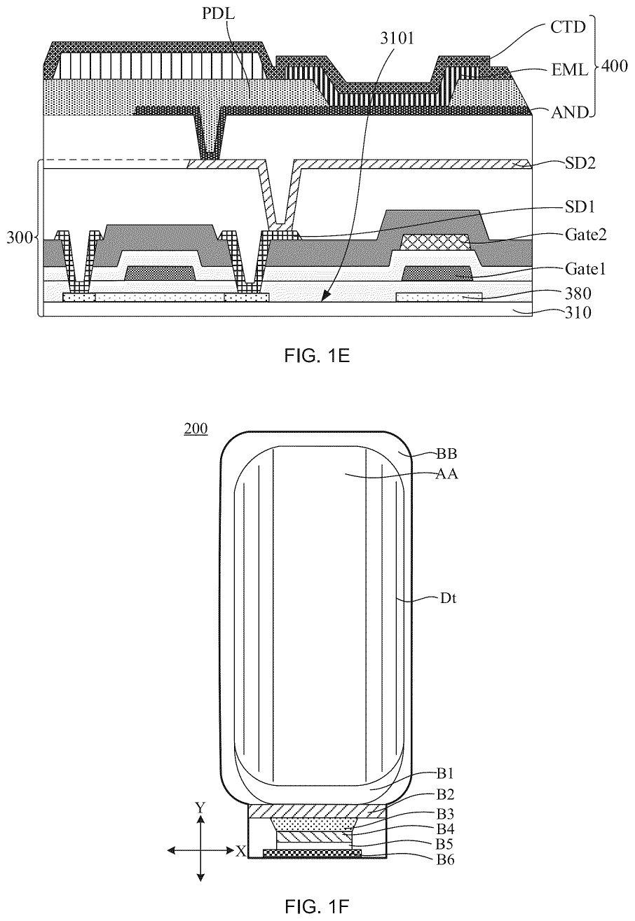

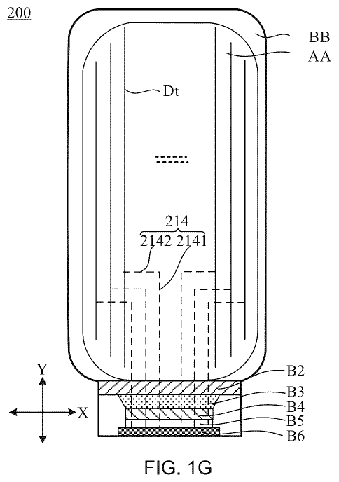

Some embodiments of the present disclosure provide a display apparatus. FIG. 1A is a structural diagram of the display apparatus, in accordance with some embodiments. Referring to FIG. 1A, the display apparatus 100 is a product having a function of displaying images (including an image in stationary or an image in motion (which may be a video)). For example, the display apparatus 100 may be any one of a display, a television, a billboard, a digital photo frame, a laser printer having a display function, a telephone, a mobile phone, a personal digital assistant (PDA), a digital camera, a portable camcorder, a view finder, a navigator, a vehicle, a large-area wall, a household appliance, an information inquiry device (e.g., a business inquiry device for a department of e-government, bank, hospital, electricity or the like) and a monitor.

The display apparatus 100 includes a display panel 200. Referring to FIG. 1B, the display panel 200 is provided with a plurality of sub-pixels 210 therein; the sub-pixels 210 are each a minimum unit of the display panel 200 for performing image display, and each sub-pixel 210 may display a single color, such as a red color (R), a green color (G) or a blue color (B). The display panel 200 is provided with red sub-pixels, green sub-pixels and blue sub-pixels therein, so as to adjust luminance (gray scales) of sub-pixels of different colors. Thus, display of a plurality of colors may be achieved by a color combination and a color superimposition, so that full-color display of the display panel 200 is achieved. As shown in FIG. 1D, each sub-pixel 210 includes a light-emitting device OLED and a pixel driving circuit 211 used for driving the light-emitting device OLED to emit light.

Referring to FIG. 1C, the display panel 200 includes an array substrate 300, a light-emitting device layer 400 and an encapsulation layer 500 that are stacked in sequence. The array substrate 300, the light-emitting device layer 400 and the encapsulation layer 500 will be respectively described below.

For example, as shown in FIG. 1E, the array substrate 300 includes a substrate 310, a plurality of functional layers sequentially arranged on the substrate 310, and insulating layers (e.g., a gate insulating layer and a buffer layer) each located between two adjacent functional layers. Referring to FIG. 1D, the substrate 310 has a display area AA and a peripheral area BB located on at least one side of the display area AA. The peripheral area BB may surround the display area AA.

Referring to FIG. 1E, the functional layers in the array substrate 300 may include an active film layer 380, a first gate metal layer Gate1, a second gate metal layer Gate2, a first source-drain metal layer SD1 and a second source-drain metal layer SD2; the active film layer 380, the first gate metal layer Gate1, the second gate metal layer Gate2, the first source-drain metal layer SD1 and the second source-drain metal layer SD2 are used for forming a plurality of pixel driving circuits 211. The plurality of pixel driving circuits 211 are disposed in the display area AA. In addition, the functional layers may be further used for forming signal lines each transmitting a signal to a pixel driving circuit 211. Referring to FIG. 1D, the signal lines may include first power supply signal lines Vdd, data lines Dt, initial signal lines Vt, gate scanning signal lines G, light-emitting control signal lines Em and reset signal lines Rst. The first power supply signal line Vdd is configured to transmit a first power supply signal, such as a voltage drain drain (VDD) signal, to the pixel driving circuit 211; the data line Dt is configured to transmit a data signal to the pixel driving circuit 211; the initial signal lines Vt is configured to transmit an initial signal Vt to the pixel driving circuit 211; the gate scanning signal lines G is configured to transmit a gate scanning signal to the pixel driving circuit 211; the light-emitting control signal lines Em is configured to transmit a light-emitting control signal to the pixel driving circuit 211; the reset signal lines Rst is configured to transmit a reset signal to the pixel driving circuit 211.

Referring to FIG. 1E, the light-emitting device layer 400 includes an anode layer AND, a light-emitting layer EML and a cathode layer CTD. The light-emitting device layer 400 is configured to form a plurality of light-emitting devices OLED. The light-emitting device OLED is electrically connected to the pixel driving circuit 211, so that the pixel driving circuit 211 drives the light-emitting device OLED to emit light.

The encapsulation layer 500 may cover the light-emitting devices OLED and encapsulate the light-emitting devices OLED, so as to prevent moisture and oxygen in the external environment from entering the display panel 200.

Referring to FIG. 1F, in some implementations, a peripheral area BB of the array substrate 300 is provided with a first fan-out region B1, a bending region B2, a second fan-out region B3, a test circuit region B4, a chip region B5 and a bonding region B6. The array substrate 300 includes the substrate 310, and the substrate 310 includes the peripheral area BB and the display area AA. A display area AA of the array substrate 300 and the display area AA of the substrate 310 are a same region, and the peripheral area BB of the array substrate 300 and the peripheral area BB of the substrate 310 are a same region.

The first fan-out region B1 is provided with lead-out portions of the data lines Dt therein, and the data lines Dt are gathered in the first fan-out region B1; the second fan-out region B3 is provided with lead-out portions of the first power supply signal lines Vdd, and the first power supply signal lines Vdd are gathered in the second fan-out region B3; the test circuit region B4 is provided with a display screen test circuit therein; the chip region B5 is provided with a driver integrated circuit (IC) bonded therein; the bonding region B6 is provided with a plurality of pins therein, and the display panel 200 may be electrically connected to a flexible circuit board via the plurality of pins. It will be noted that the bending region B2 is made of a flexible material, and may be bendable; the bending region B2, the second fan-out region B3, the test circuit region B4, the chip region B5 and the bonding region B6 need to be folded onto a back surface of the display panel 200, thereby reducing a width of a bezel of the display panel 200 and satisfying a requirement for “a small chin” of the display panel 200.

In another implementation, the first fan-out region is designed to be inside the display area AA. That is, fan-out lines in the first fan-out region are gathered in the display area AA, so that the width of the bezel of the display panel is reduced. For example, referring to FIG. 1G, the array substrate 300 is provided with data lines Dt and fan-out lines 214 therein, and the data lines Dt each extend in a first direction Y. A fan-out line 214 includes a first sub-line 2141 extending in the first direction Y and a second sub-line 2142 extending in a second direction X, and the first direction Y intersects the second direction X. For example, the first direction Y may be perpendicular to the second direction X. The first sub-line 2141 extends from the peripheral area BB to the display area AA; an end of the second sub-line 2142 is electrically connected to an end of the first sub-line 2141 located in the display area AA, and another end of the second sub-line 242 away from the first sub-line 2141 is electrically connected to one of the data lines Dt. so that the fan-out line 214 may transmit a data signal to the data line Dt corresponding to the fan-out line 214. It will be noted that “the data line Dt corresponding to the fan-out line 214” here refers to the data line Dt electrically connected to the fan-out line 214.

In the array substrate 300 provided in the implementations, referring to FIG. 1F, the first fan-out region B1 is disposed in the peripheral area BB, the first fan-out region B1 is not folded onto the back surface of the display panel 200 after the bending region B2, the second fan-out region B3, the test circuit region B4, the chip region B5 and the bonding region B6 are folded onto the back surface of the display panel, and thus the first fan-out region B1 forms the bezel of the display panel 200. In the array substrate 300 provided in the implementation shown in FIG. 1G, the fan-out lines 214 are gathered in the display area AA, which is equivalent to arranging the first fan-out region in the display area AA, so that the first fan-out region is not in the bezel of the display panel 200 after the bending region B2, the second fan-out region B3, the test circuit region B4, the chip region B5 and the bonding region B6 are folded onto the back surface of the display panel 200. As a result, the bezel of the display panel 200 may be narrowed.

In some examples, the initial signal lines are disposed in the first source-drain metal layer SD1, and the first power supply signal lines Vdd and the data lines Dt are disposed in the second source-drain metal layer SD2, so that a distance between the data lines Dt and an underlying structure is relatively large. As a result, a capacitance of a capacitor formed by the data lines Dt and the underlying structure (e.g., the first gate metal layer Gate1, the second gate metal layer Gate2 or the active film layer 380) is relatively small, so that the display panel 200 may support high-frequency display. However, the first sub-line 2141 and the second sub-line 2142 of the fan-out line 214 are both disposed in a third source-drain metal layer. When the display panel 200 is manufactured, there is a need to add two masks specially for the fan-out lines 214. For example, after the second source-drain metal layer SD2 is manufactured, there is a need to manufacture a planarization layer to cover the second source-drain metal layer SD2; and then, the third source-drain metal layer is formed on the planarization layer. In order to ensure signal lines in the third source-drain metal layer to be electrically connected to underlying structures (e.g., the second source-drain metal layer SD2, the first source-drain metal layer SD1 and the second gate metal layer Gate2), there is a need to punch the planarization layer to enable the third source-drain metal layer to be connected to the underlying structures (e.g., the second source-drain metal layer SD2, the first source-drain metal layer SD1 and the second gate metal layer Gate2) through respective via holes. A mask is needed for punching the planarization layer, and another mask is needed for manufacturing the fan-out lines 214. Thus, two additional masks are needed for forming the fan-out lines 214. Therefore, in these examples, when the array substrate 300 is manufactured, a relatively large number of masks are needed, so that a cost is relatively high.

In summary, the array substrate 300 in the display panel 200 provided in the above examples cannot achieve the high-frequency design by using a relatively small number of masks.

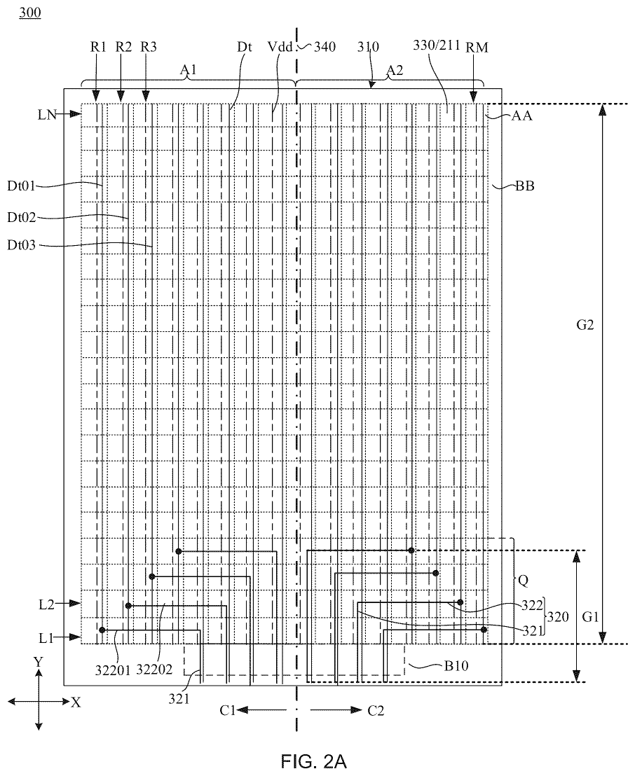

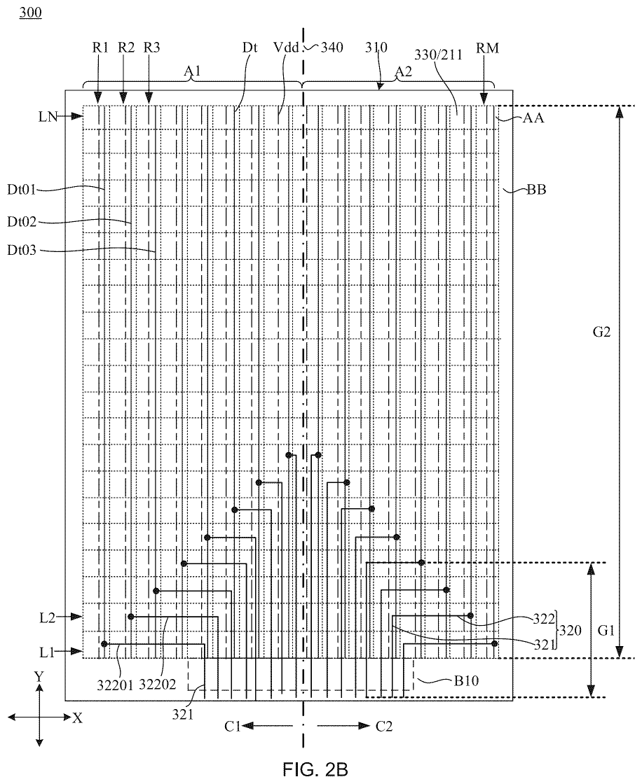

In light of this, some embodiments of the present disclosure provide an array substrate 300, referring to FIGS. 2A and 2B, the array substrate 300 includes a substrate 310, a plurality of first power supply signal lines Vdd, a plurality of data lines Dt and a plurality of fan-out lines 320.

Referring to FIGS. 2A and 2B, the substrate 310 has a display area AA and a peripheral area BB, and the display area AA has sub-pixel regions 330 arranged in a plurality of rows and a plurality of columns. The sub-pixel regions 330 in the display area AA may be arranged in an array. Pixel driving circuits 211 may be respectively disposed in the sub-pixel regions 330, so that the pixel driving circuits 211 are arranged in the array on the substrate 310.

A first power supply signal line Vdd and a data line Dt both corresponding to a same column of sub-pixel regions are all located within the column of sub-pixel regions, and the first power supply signal line Vdd and the data line Dt both corresponding to the same column of sub-pixel regions are all electrically connected to pixel driving circuits in the same column. It will be noted that “a first power supply signal line Vdd corresponding to a column of sub-pixel regions” refers to that an orthographic projection of the first power supply signal line Vdd on the substrate 310 is located within the column of sub-pixel regions. Similarly, “a data line Dt corresponding to a column of sub-pixel regions” refers to that an orthographic projection of the data line Dt on the substrate 310 is located within the column of sub-pixel regions.

The plurality of first power supply signal lines Vdd are located on a first side 3101 (as shown in FIG. 1E) of the substrate 310 and located in the display area AA. The plurality of first power supply signal lines Vdd each extend in a first direction Y and are sequentially arranged in a second direction X. The second direction X intersects the first direction Y, and the second direction X and the first direction Y are both parallel to the substrate 310. The first direction Y may be perpendicular to the second direction X. Sub-pixel regions 330 in each column of sub-pixel regions may be sequentially arranged in the first direction Y, and sub-pixel regions 330 in each row of sub-pixel regions may be sequentially arranged in the second direction X. The first power supply signal line Vdd extends in the first direction Y, so as to transmit a first power supply signal to the pixel driving circuits in the column of sub-pixel regions.

The plurality of data lines Dt are located on the first side 3101 of the substrate 310 and located in the display area AA. Referring to FIGS. 2A and 2B, the plurality of data lines Dt each extend in the first direction Y and are sequentially arranged in the second direction X. A data line Dt is adjacent to a first power supply signal line Vdd. The data line Dt extends in the first direction Y, so as to transmit a data signal to the respective pixel driving circuit in the column of sub-pixel regions.

The plurality of fan-out lines 320 are located on the first side 3101 of the substrate 310. Referring to FIGS. 2A and 2B, a fan-out line 320 includes a first sub-line 321 and a second sub-line 322. The first sub-line 321 extends in the first direction Y and extends from the peripheral area BB to the display area AA. The second sub-line 322 extends in the second direction X and is located in the display area AA. An end of the second sub-line 322 is electrically connected to the first sub-line 321, another end of the second sub-line 322 is electrically connected to a data line Dt of the plurality of data lines Dt, and the second sub-line 322 is insulated from remaining data lines Dt of the plurality of data lines Dt.

In some examples, referring to FIG. 2A, the plurality of fan-out lines 320 are electrically connected to a part of the plurality of data lines Dt in a one-to-one correspondence. The fan-out lines 320 each include a second sub-line 322. It will be understood that the second sub-lines 322 may be electrically connected to the part of the plurality of data lines Dt in a one-to-one correspondence. In some examples, the data lines electrically connected to the fan-out lines 320 are respectively disposed on two sides, in the second direction X, of data lines not electrically connected to the fan-out lines 320. In addition, a part of the data lines not electrically connected to the fan-out lines 320 and a part of first sub-lines 321 may be arranged alternately. That is, the part of the data lines not electrically connected to the fan-out lines 320 may be each located between two first sub-lines 321.

In some other examples, referring to FIG. 2B, the plurality of fan-out lines 320 are electrically connected to the plurality of data lines Dt in a one-to-one correspondence, and a fan-out line 320 may transmit a data signal to a data line Dt corresponding to the fan-out line 320. The fan-out lines 320 each include a second sub-line 322. It will be understood that the second sub-lines 322 may be electrically connected to the plurality of data lines Dt in a one-to-one correspondence.

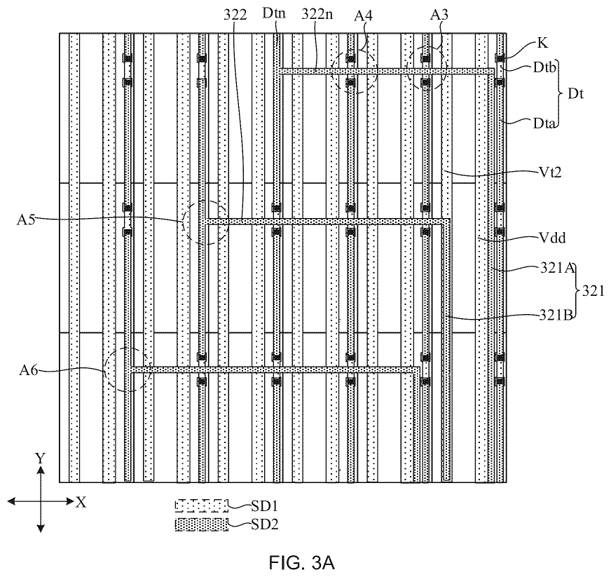

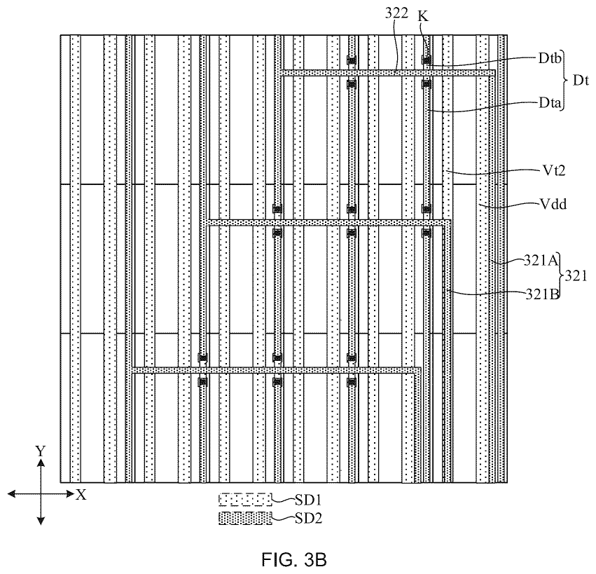

The end of the second sub-line 322 is electrically connected to an end of the first sub-line 321 located in the display area AA, and the other end of the second sub-line 322 is electrically connected to the data line Dt corresponding thereto. The second sub-line 322 may cross data lines Dt not corresponding to the second sub-line 322, and extend to the data line Dt corresponding to the second sub-line 322 and be electrically connected to the data line Dt. The second sub-line 322 is electrically connected to the data line Dt corresponding thereto and insulated from the data lines Dt that the second sub-line 322 crosses. It will be noted that a second sub-line 322 is electrically connected to one of the plurality of data lines Dt, the second sub-line 322 and the data line Dt that are electrically connected to each other correspond to each other, and a data line Dt and a second sub-line 322 that are not electrically connected to each other do not correspond to each other. It can be seen from the above that the term “cross” refers to that an orthographic projection of the second sub-line 322 on the substrate 310 intersects orthographic projections, on the substrate 310, of the data lines Dt that the second sub-line 322 crosses. Referring to FIG. 3A, in the region A3 and the region A4, a second sub-line 322 crosses data lines Dt. In the region A5 and the region A6, orthographic projections of second sub-lines 322 on the substrate 310 do not intersect orthographic projections of respective data lines Dt on the substrate 310. That is, the second sub-lines 322 do not cross the respective data lines Dt.

In some examples, as shown in FIGS. 2A and 2B, there are M columns of sub-pixel regions and N rows of sub-pixel regions that are disposed in the substrate 310. The N rows of sub-pixel regions sequentially arranged in the first direction Y are a first row L1 of sub-pixel regions, a second row L2 of sub-pixel regions, . . . , an N-th row LN of sub-pixel regions. The M columns of sub-pixel regions sequentially arranged in the second direction X are a first column R1 of sub-pixel regions, a second column R2 of sub-pixel regions, . . . , an M-th column RM of sub-pixel regions.

In some examples, the part of the data lines Dt are electrically connected to the fan-out lines 320, respectively. In this case, the number of the fan-out lines 320 is less than M. Of course, in some other examples, as shown in FIG. 2B, the plurality of data lines Dt are electrically connected to the fan-out lines 320 in a one-to-one correspondence. In this case, there are M data lines Dt disposed in the array substrate 300, and thus there are M fan-out lines 320, i.e., M second sub-lines 322 and M first sub-lines 321, disposed in the array substrate 300.

As shown in FIGS. 2A and 2B, in the second sub-lines 322, a second sub-line 32201 that is electrically connected to a data line Dt01 corresponding to the first column R1 of sub-pixel regions crosses a data line Dt02 corresponding to the second column R2 of sub-pixel regions, a data line Dt03 corresponding to the third column R3 of sub-pixel regions and so on; the second sub-line 32201 is insulated from the data line Dt02 corresponding to the second column R2 of sub-pixel regions, the data line Dt03 corresponding to the third column R3 of sub-pixel regions and so on.

For example, an insulating layer may be provided between the second sub-line 322 and the data lines Dt that the second sub-line 322 crosses, so that the second sub-line 322 is insulated from the data lines Dt that the second sub-line 322 crosses.

In addition, referring to FIG. 1F, in the display panel 200 provided in some implementations, the first fan-out region B1 is disposed in the peripheral area BB, the first fan-out region B1 is not folded onto the back surface of the display panel 200 after the bending region B2, the second fan-out region B3, the test circuit region B4, the chip region B5 and the bonding region B6 are folded onto the back surface of the display panel 200, and thus the first fan-out region B1 forms the bezel of the display panel 200. In the array substrate 300 provided in some embodiments of the present disclosure, the fan-out lines 320 are gathered in the display area AA, which is equivalent to arranging the first fan-out region in the display area AA. As a result, after the bending region B2, the second fan-out region B3, the test circuit region B4, the chip region B5 and the bonding region B6 are folded onto the back surface of the display panel 200, the bezel of the display panel 200 does not include the first fan-out region, so that the bezel of the display panel 200 may be narrowed.

Main structures of the data lines Dt are located on a side of the first power supply signal lines Vdd away from the substrate 310. In some embodiments, the main structures of the data lines Dt are each a complete data line Dt. In some other embodiments, referring to FIG. 3A, the main structures of the data lines Dt each include a plurality of main lines Dta; two adjacent main lines Dta are electrically connected to each other via a jumper wire Dtb, so as to constitute a complete data line Dt. The main structures of the data lines Dt are located on the side of the first power supply signal lines Vdd away from the substrate 310. Thus, a distance between the data lines Dt and an underlying structure (e.g., the second gate metal layer Gate2, the first gate metal layer Gate1 or the active film layer 380) is relatively large, so that a capacitance created between the data lines Dt and the underlying structure is relatively small. As a result, it is possible to support the high-frequency display of the display panel 200. For example, the first power supply signal lines Vdd are disposed in the first source-drain metal layer SD1, and the main structures of the data lines Dt are disposed in the second source-drain metal layer SD2.

The first sub-line 321 and the main structures of the data lines Dt are disposed in a same layer. The main structures of the data lines Dt and the first sub-line 321 are disposed in the same layer, which makes it possible to manufacture the main structures of the data lines Dt and the first sub-line 321 by using a same mask, so that there is no need to provide another mask for manufacturing the first sub-line 321. Therefore, a relatively small number of masks may be used during a process of manufacturing the display panel 200, thereby saving the cost.

Referring to FIGS. 2A and 2B, an orthographic projection, on the substrate 310, of a first sub-line 321 passing through a column of sub-pixel regions 330 is substantially located between an orthographic projection, on the substrate 310, of a corresponding first power supply signal line Vdd passing through the column of sub-pixel regions 330 and an orthographic projection, on the substrate 310, of a data line Dt passing through the column of sub-pixel regions 330.

It will be noted that “a first sub-line 321 passing through a column of sub-pixel regions” refers to that an orthographic projection of the first sub-line 321 on the substrate 310 is located within a part or all of the sub-pixel regions in the column. Similarly, “a corresponding first power supply signal line Vdd passing through a column of sub-pixel regions” refers to that an orthographic projection of the first power supply signal line Vdd on the substrate 310 is located within a part or all of the sub-pixel regions in the column; “a data line Dt passing through a column of sub-pixel regions” refers to that an orthographic projection of the data line Dt on the substrate 310 is located within a part or all of the sub-pixel regions in the column.

Moreover, it will be noted that a description that the orthographic projection, on the substrate 310, of the first sub-line 321 passing through the column of sub-pixel regions is substantially located between the orthographic projection, on the substrate 310, of the corresponding first power supply signal line Vdd passing through the column of sub-pixel regions and the orthographic projection, on the substrate 310, of the data line Dt passing through the column of sub-pixel regions may include but is not limited to the following cases: \textcircled{1} the orthographic projection of the first sub-line 321 is located between the orthographic projection of the first power supply signal line Vdd and the orthographic projection of the data line Dt that are located within the same column of sub-pixel regions; \textcircled{2} a main body portion of the orthographic projection of the first sub-line 321 is located between the orthographic projection of the first power supply signal line Vdd and the orthographic projection of the data line Dt that are located in the same column of sub-pixel regions; that is, the first sub-line 321 may partially overlap with the first power supply signal line Vdd and/or the data line Dt of which the first power supply signal line Vdd and the data line Dt are located in the same column of sub-pixel regions; \textcircled{3} an orthographic projection of a middle line of the first sub-line 321 is located between an orthographic projection of a middle line of the first power supply signal line Vdd and an orthographic projection of a middle line of the data line Dt that are located in the same column of sub-pixel regions.

In some examples, multiple first sub-lines 321 may each pass through a different column of sub-pixel regions. In this case, a first sub-line 321 corresponds to a column of sub-pixel regions. In some other examples, multiple first sub-lines 321 may each pass through a same column of sub-pixel regions. In this case, the column of sub-pixel regions correspond to the multiple first sub-lines 321. In some examples, referring to FIGS. 3A and 3B, a column of sub-pixel regions correspond to two first sub-lines 321, and the two first sub-lines 321 corresponding to the column of sub-pixel regions are respectively a first first sub-line 321A and a second first sub-line 321B.

Referring to FIGS. 3A and 3B, the first first sub-line 321A, a first power supply signal line Vdd and a data line Dt all correspond to the same column of sub-pixel regions, and an orthographic projection of the first first sub-line 321A on the substrate 310 is located between an orthographic projection of the first power supply signal line Vdd on the substrate 310 and an orthographic projection of the data line Dt on the substrate 310. Therefore, the first first sub-line 321A is non-overlapping with the first power supply signal line Vdd, so that crosstalk created between a data signal on the first first sub-line 321A and a first power supply signal on the first power supply signal line Vdd may be avoided.

In summary, the array substrate 300 provided in the embodiments of the present disclosure may satisfy the requirement for the high-frequency display of the display panel 200; furthermore, there is no need to provide additional mask for the provision of the first sub-line 321. As a result, the number of masks used during the process of manufacturing the display panel 200 is reduced, thereby saving the cost.

Based on the array substrate 300 provided in some of the above embodiments, a wiring manner of the fan-out lines 320 disposed in the array substrate 300 will be described below.

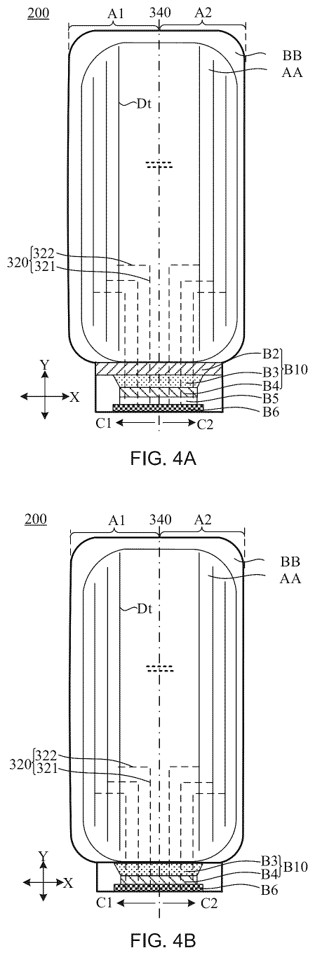

In some embodiments, referring to FIGS. 2A, 2B and 4A, the peripheral area BB includes a lead-out region B10 located on a side of the display area AA. The first sub-lines 321 each extend from the lead-out region B10 to the display area AA.

In some examples, referring to FIG. 4A, the lead-out region B10 includes a bending region B2, a second fan-out region B3 and a test circuit region B4. A chip region B5 is provided on a side of the lead-out region B10 away from the display area AA. The first sub-lines 321 may each extend to the chip region B5, and the first sub-lines 321 are bonded and electrically connected to a driver IC in the chip region B5. In some examples, referring to FIG. 2A, the plurality of fan-out lines 320 are electrically connected to the part of the plurality of data lines Dt in a one-to-one correspondence. The data lines Dt not electrically connected to the fan-out lines 320 each extend to the chip region B5 through the lead-out region B10.

In some other examples, the lead-out region B10 does not include the bending region B2, and there is no chip region B5 provided on the side of the lead-out region B10 away from the display area AA. In this case, referring to FIG. 4B, the lead-out region B10 includes the second fan-out region B3 and the test circuit region B4, and a bonding region B6 is provided on the side of the lead-out region B10 away from the display area AA. In this case, the first sub-lines 321 may each extend to the bonding region B6 through the lead-out region B10 and be electrically connected to a plurality of pins in the bonding region B6. The driver IC is bonded to a flexible circuit board, and the flexible circuit board is bonded to the plurality of pins in the bonding region. In this example, the flexible circuit board is folded onto the back surface of the display panel 200. In some examples, referring to FIG. 2A, the plurality of fan-out lines 320 are electrically connected to the part of the plurality of data lines Dt in a one-to-one correspondence. The data lines Dt not electrically connected to the fan-out lines 320 each extend to the bonding region B6 through the lead-out region B10.

In some embodiments, referring to FIGS. 2A, 2B, 4A and 4B, a direction from a center line 340, in the second direction X, of the display area AA to any side of the display area AA in the second direction X is a first setting direction. The display area AA is divided into two display sub-regions by the center line 340 of the display area AA in the second direction X, and a direction from the center line 340 to any display sub-region is the first setting direction. For example, the two display sub-regions are a first region A1 and a second region A2. In the first region A1, a direction represented by the arrow C1 is the first setting direction; in the second region A2, a direction represented by the arrow C2 is the first setting direction.

In some examples, referring to FIGS. 2A, 2B, 4A and 4B, lengths of portions, located in the display area AA, of the first sub-lines 321 sequentially decrease in the first setting direction. In any display sub-region, lengths of portions, located in the display area AA, of first sub-lines 321 sequentially decrease in the first setting direction. That is, in the first region A1, lengths, in the first direction Y, of portions, located in the display area AA, of first sub-lines 321 sequentially decrease in the first setting direction C1; in the second region A2, lengths, in the first direction Y, of portions, located in the display area AA, of other first sub-lines 321 sequentially decrease in the first setting direction C2.

In each display sub-region, referring to FIGS. 2A and 2B, the first sub-lines 321 each extend to a different row of sub-pixel regions. Thus, the second sub-lines 322 electrically connected to the first sub-lines 321 each correspond to a different row of sub-pixel regions, so that the second sub-lines 322 each extend to a different data line Dt and is electrically connected to the respective data line Dt.

A direction from an end of a second sub-line 322 connected to a first sub-line 321 to a data line Dt electrically connected to the second sub-line 322 is an extending direction of the second sub-line 322. Extending directions of second sub-lines 322 respectively located on two sides of the center line 340 are opposite to each other. The extending direction of the second sub-line 322 is the same as a first setting direction of a display sub-region where the second sub-line 322 is located.

In some embodiments, as shown in FIGS. 2A and 2B, a length G1 of at least one first sub-line 321 is not greater than half a dimension G2 of the display area AA in the first direction Y.

In some examples, lengths of some of the first sub-lines 321 may be each not greater than half the dimension of the display area AA in the first direction Y, and lengths of remaining first sub-lines 321 may be each greater than half the dimension of the display area AA in the first direction Y. In some other examples, lengths of all the first sub-lines 321 may be each not greater than half the dimension of the display area AA in the first direction Y.

Of course, in some other implementations, the lengths of all the first sub-lines 321 may be each greater than half the dimension of the display area AA in the first direction Y.

For example, there are M columns of sub-pixel regions and N rows of sub-pixel regions that are disposed in the substrate 310. In some examples, referring to FIG. 2A, the plurality of fan-out lines 320 may be electrically connected to a part of all the data lines Dt in a one-to-one correspondence. In this case, the number of the fan-out lines 320 may be less than M. In some other examples, referring to FIG. 2B, the plurality of fan-out lines 320 may be electrically connected to all the data lines Dt in a one-to-one correspondence. In this case, there are M data lines Dt disposed in the array substrate 300, and thus there are M fan-out lines 320 disposed in the array substrate 300. That is, M second sub-lines 322 may be electrically connected to M first sub-lines 321 in a one-to-one correspondence.

For example, referring to FIGS. 2A and 2B, the dimension G2 of the display area AA in the first direction Y is greater than a dimension of the display area AA in the second direction X, and in the display area AA, the number of the rows of the sub-pixel regions 330 is greater than the number of the columns of the sub-pixel regions 330. That is, N is greater than M.

In some examples, referring to FIGS. 2A and 2B, a row of sub-pixel regions may correspond to multiple second sub-lines 322, and the multiple second sub-lines 322 corresponding to the same row of sub-pixel regions each pass through different sub-pixel region(s) 330. That is, orthographic projections, on the substrate 310, of the multiple second sub-lines 322 corresponding to the same row of sub-pixel regions are non-overlapping with each other. Therefore, multiple first sub-lines 321 may be enabled to extend to a same row of sub-pixel regions, which may reduce a maximum dimension of the first sub-lines 321 in the first direction Y. For example, a row of sub-pixel regions may correspond to two second sub-lines 322, and correspondingly, the two of the first sub-lines 321 may extend to the same row of sub-pixel regions. For example, a first sub-line 321, the farthest away from the center line 340, in the first region A1 and a first sub-line 321, the farthest away from the center line 340, in the second region A2 both extend to the first row L1 of sub-pixel regions. In this case, the first row L1 of sub-pixel regions correspond to two second sub-lines 321.

Based on the examples where a row of sub-pixel regions may correspond to two second sub-lines 321, referring to FIG. 2A, in a case where the plurality of fan-out lines 320 may be electrically connected to the part of all the data lines Dt in a one-to-one correspondence, the number of the second sub-lines 322 is less than M. In this case, in the N rows of sub-pixel regions, the number of rows of sub-pixel regions where the second sub-lines 322 are disposed is less than M/2. For convenience of description, the number of the rows of the sub-pixel regions where the second sub-lines 322 are disposed is defined as Q. Therefore, the first sub-line 321 with the maximum dimension in the first direction Y may pass through at least the Q rows of sub-pixel regions; where Q is less than M/2.

Referring to FIG. 2B, in a case where the plurality of fan-out lines 320 may be electrically connected to all the data lines Dt in a one-to-one correspondence, in the N rows of sub-pixel regions, M/2 rows of sub-pixel regions may overlap with orthographic projections of the M second sub-lines 322 on the substrate 310, and remaining (N-M/2) rows of sub-pixel regions are non-overlapping with the orthographic projections of the second sub-lines 322 on the substrate 310. In this case, the first sub-line 321 with the maximum dimension in the first direction Y passes through at least the M/2 rows of sub-pixel regions.

In some examples, referring to FIGS. 2A and 2B, in a display sub-region, two adjacent first sub-lines 321 may respectively extend to two adjacent rows of sub-pixel regions, and a second sub-line 322 connected to the first sub-line 321 that is the farthest away from the center line 340 extends in the first row L1 of sub-pixel regions.

In this case, referring to FIG. 2A, in the case where the plurality of fan-out lines 320 may be electrically connected to the part of all the data lines Dt in a one-to-one correspondence, the first sub-line 321 with the maximum dimension in the first direction Y may pass through from the first row L1 of sub-pixel regions to a Q-th row of sub-pixel regions. That is, the first sub-line 321 with the maximum dimension in the first direction Y passes through Q rows of sub-pixel regions. N is greater than M (which means that M/2 is less than N/2), and Q is less than M/2, so that the first sub-line 321 with the maximum dimension in the first direction Y passes through less than N/2 sub-pixel regions 330. As a result, a length, in the display area AA, of any first sub-line 321 is not greater than half the dimension of the display area AA in the first direction Y.

Referring to FIG. 2B, in the case where the plurality of fan-out lines 320 may be electrically connected to all the data lines Dt in a one-to-one correspondence, the first sub-line 321 with the maximum dimension in the first direction Y may pass through from the first row L1 of sub-pixel regions to an (M/2)-th row of sub-pixel regions. That is, the first sub-line 321 with the maximum dimension in the first direction Y passes through M/2 rows of sub-pixel regions. N is greater than M (which means that M/2 is less than N/2), so that the first sub-line 321 with the maximum dimension in the first direction Y passes through less than N/2 sub-pixel regions 330. As a result, a length, in the display area AA, of any first sub-line 321 is not greater than half the dimension of the display area AA in the first direction Y.

In some other examples, in a display sub-region, two adjacent first sub-lines 321 may respectively extend to two adjacent rows of sub-pixel regions, and there may be multiple rows of sub-pixel regions between a second sub-line 322 that is closest to the lead-out region B10 and the lead-out region B10. For example, there may be P rows of sub-pixel regions between the second sub-line 322 that is closest to the lead-out region B10 and the lead-out region B10. In this case, the first sub-line 321 with the maximum dimension in the first direction Y passes through (P+M/2) rows of sub-pixel regions.

In yet other examples, in a display sub-region, two adjacent first sub-lines 321 may respectively extend to two rows of sub-pixel regions that are arranged at intervals. In this case, two respective second sub-lines 322, adjacent to each other in the first direction Y, are respectively disposed in the two rows of sub-pixel regions that are arranged at intervals. For example, there are one or more rows of sub-pixel regions between two rows of sub-pixel regions where two second sub-lines 322, adjacent to each other in the first direction Y, are respectively located.

In yet other examples, in a display sub-region, there is none of the rows of sub-pixel regions or one row of sub-pixel regions or multiple rows of sub-pixel regions between two rows of sub-pixel regions where two second sub-lines 322, adjacent to each other in the first direction Y, are respectively located. In a case where there is none of the rows of sub-pixel regions between two rows of sub-pixel regions where two second sub-lines 322, adjacent to each other in the first direction Y, are respectively located, the two rows of sub-pixel regions, in which the two second sub-lines 322 adjacent to each other in the first direction Y are respectively located, are adjacent to each other.

In some embodiments, referring to FIGS. 2A and 2B, the closer a first sub-line 321 is to the center line 340 of the display area AA in the second direction X, the farther a second sub-line 322 connected to the first sub-line 321 is away from the lead-out region B10. The farther the second sub-line 322 is away from the lead-out region B10, the closer a data line Dt connected to the second sub-line 322 is to the center line 340 of the display area AA in the second direction X.

For example, the center line 340 of the display area AA in the second direction X extends in the first direction Y.

In the display sub-region, in the first setting direction, the second sub-lines 322 to which the first sub-lines 321 are electrically connected gradually approach the lead-out region B10. A second sub-line 322, to which a first sub-line 321 the closest to the center line 340 is electrically connected, is the farthest away from the lead-out region B10. Therefore, the second sub-lines 322 to which the first sub-lines 321 are electrically connected do not overlap. The first sub-line 321 the farthest away from the center line 340 of the display area AA in the second direction X is electrically connected to a data line Dt the farthest away from the center line 340, and a dimension of the first sub-line 321 in the first direction Y is the smallest; the first sub-line 321 the closest to the center line 340 of the display area AA in the second direction X is electrically connected to a data line Dt the closest to the center line 340, and a dimension of the first sub-line 321 in the first direction Y is the largest.

For example, referring to FIGS. 2A and 2B, the first row L1 of sub-pixel regions correspond to a second sub-line 32201 the closest to the lead-out region B10, and the data line Dt01 to which the first column R1 of sub-pixel regions correspond is electrically connected to the second sub-line 32201 to which the first row L1 of sub-pixel regions correspond, so that the data line Dt01 to which the first column R1 of sub-pixel regions correspond does not cross any one of the second sub-lines 322. The data line Dt02 to which the second column R2 of sub-pixel regions correspond is electrically connected to a second sub-line 32202 to which the second row L2 of sub-pixel regions correspond, so that the data line Dt02 to which the second column R2 of sub-pixel regions correspond may cross the second sub-line 32201 to which the first row L1 of sub-pixel regions correspond, and so on.

In the above wiring manner, the fan-out lines 320 may be relatively short, which may save the cost.

In some embodiments, referring to FIG. 4A, all the first sub-lines 321 are substantially symmetric with the center line 340 of the display area AA in the second direction X as a line of symmetry. Moreover, all the second sub-lines 322 are substantially symmetric with the center line 340 of the display area AA in the second direction X as a line of symmetry. In the embodiments of the present disclosure, the phrase “substantially symmetric” refers to that a difference between a distance between a structure located on a side of the center line 340 and the center line 340 and a distance between a structure located on another side of the center line 340 and the center line 340 is within 5%.

Referring to FIG. 4A, the fan-out lines 320 are symmetrically arranged in the array substrate 300, and the first sub-lines 321 may be gathered in a middle of the lead-out region B10. The center line 340 of the display area AA in the second direction X is also a center line 340 of the lead-out region B10 in the second direction X, and the middle of the lead-out region B10 is a partial region extending to the two sides with the center line 340 of the lead-out region B10 in the second direction X as the center, and a dimension, in the second direction X, of the middle of the lead-out region B10 is less than a dimension, in the second direction X, of the entire lead-out region B10.

All the first sub-lines 321 and all the second sub-lines 322 are each substantially symmetric with the center line 340 of the display area AA in the second direction X as the line of symmetry. That is, the fan-out lines 320 are substantially symmetric with the center line 340 as the line of symmetry. As a result, a total structure of the fan-out lines 320 is regular, which facilitates processing, so that convenience of production and processing is improved.

In some embodiments, referring to FIGS. 3A and 3B, a main structure of the data line Dt includes a plurality of main lines Dta, and the data line Dt further includes at least one jumper wire Dtb; the jumper wire Dt and the first power supply signal line Vdd are disposed in a same layer; in the same data line Dt, the jumper wire(s) Dtb and the main lines Dta are alternately electrically connected to one another through via holes K.

The main lines Dta are disposed on the side of the first power supply signal line Vdd away from the substrate 310, and the jumper wire(s) Dtb and the first power supply signal line Vdd are disposed in the same layer. Thus, the main lines Dta are disposed in a layer different from a layer where the jumper wire(s) Dtb are disposed, and the adjacent main line Dta and jumper wire Dtb may be electrically connected to each other through a via hole K.

In some examples, a dimension, in the first direction Y, of the main line Dta is greater than a dimension, in the first direction Y, of the jumper wire Dtb.

In some examples, each data line Dt includes main lines Dta and jumper wire(s) Dtb that are arranged alternately. In some other examples, some data lines Dt (e.g., the data line Dt01 to which the first column R1 of sub-pixel regions correspond as shown in FIGS. 2A and 2B) each include only a main line Dta and no jumper wire Dtb; remaining data lines Dt (e.g., the data line Dt02 to which the second column R2 of sub-pixel regions correspond and the data line Dt03 to which the third column R3 of sub-pixel regions correspond as shown in FIG. 2B) each include main lines Dta and jumper wires Dtb that are arranged alternately.

In some examples, referring to FIG. 3B, a data line Dt may be provided with a jumper wire Dtb only at a position where the data line Dt passes through a second sub-line 322. In some other examples, referring to FIG. 3A, a data line Dt may be further provided with a jumper wire Dtb at another position, in addition to a position where the data line Dt passes through a second sub-line 322.

In some embodiments, referring to FIG. 3A, the second sub-lines 322 and the main lines Dta are disposed in the same layer, and each of at least one second sub-line 322 crosses a jumper wire Dtb of at least one data line Dt. Here, the term “cross” refers to that an orthographic projection of the second sub-line 322 on the substrate 310 intersects an orthographic projection of the jumper wire Dtb on the substrate 310, and an orthographic projection, on the substrate 310, of an end of the second sub-line 322 away from a respective first sub-line 321 does not coincide with the orthographic projection of the jumper wire Dtb on the substrate 310. For example, referring to FIG. 3A, in the region A3 and the region A4, a second sub-line 322 crosses jumper wires Dtb. In the region A5 and the region A6, data lines Dt each coincide with an end of a respective second sub-line 322 away from a respective first sub-line 321. That is, in the region A5 and the region A6, the second sub-lines 322 do not cross the respective data lines Dt.

Data line(s) Dt each further include at least one jumper wire Dtb, and at least one second sub-line 322 crosses a jumper wire Dtb of at least one data line Dt. In some examples, it is possible that only a single data line Dt of the plurality of data lines Dt is provided with jumper wire(s) Dtb, and a second sub-line 322 crosses the single data line Dt. In some other examples, it is possible that some of the plurality of data lines Dt are each provided with jumper wire(s) Dtb, and a second sub-line 322 may cross all the jumper wires Dtb of the plurality of data lines Dt. In yet other examples, it is possible that at least some of the plurality of data lines Dt are each provided with jumper wire(s) Dtb, and the second sub-lines 322 may respectively cross all the jumper wires Dtb of the plurality of data lines Dt. In yet other examples, it is possible that at least some of the plurality of data lines Dt are each provided with jumper wire(s) Dtb, the second sub-lines 322 may respectively cross some of all the jumper wires Dtb of the plurality of data lines Dt, and an orthographic projection, on the substrate 310, of the rest of all the jumper wires Dtb of the plurality of data lines Dt is non-overlapping with the orthographic projections of the second sub-lines 322 on the substrate 310.

The second sub-lines 322 and the main lines Dta are disposed in the same layer, and the first sub-lines 321 and the main lines Dta are disposed in the same layer, so that the fan-out lines 320 and the main lines Dta are disposed in the same layer. Thus, the fan-out lines 320 and the main lines Dta may be formed during a same process by using a same mask, so that there is no need to provide additional mask for the fan-out lines 320. As a result, the number of masks used during the process of manufacturing the display panel 200 is reduced, thereby saving the cost. For example, referring to FIGS. 3A and 3B, the first sub-lines 321, the second sub-lines 322 and the main lines Dta are disposed in the second source-drain metal layer SD2.

The second sub-lines 322 and the main lines Dta are disposed in the same layer, and the jumper wires Dtb are disposed in the layer different from the layer where the main lines Dta are disposed. Thus, the second sub-lines 322 are disposed in the layer different from the layer where the jumper wires Dtb are disposed. A second sub-line 322 may cross jumper wire(s) Dtb of data lines Dt not corresponding thereto, so that the second sub-line 322 may be insulated from the data lines Dt not corresponding thereto. For example, referring to FIGS. 3A and 3B, the jumper wires Dtb are disposed in the first source-drain metal layer SD1.

An arrangement manner of the jumper wires Dtb is described in some of the above embodiments, and a connection manner between the data line Dt and the second sub-line 322 will be described below based on the embodiments in which the data line Dt includes the jumper wire(s) Dtb.

In some embodiments, a second sub-line 322 may be electrically connected to a main line Dta of a data line Dt to which the second sub-line 322 corresponds. For example, referring to FIG. 3A, a second sub-line 322n corresponds to a data line Dtn; at a position where the data line Dtn is electrically connected to the second sub-line 322n, the data line Dtn is provided with no jumper wire Dtb, but provided with a main line Dta. Thus, the second sub-line 322n is electrically connected to the main line Dta of the data line Dtn, and the main line Dta of the data line Dtn passes through an end of the second sub-line 322n.

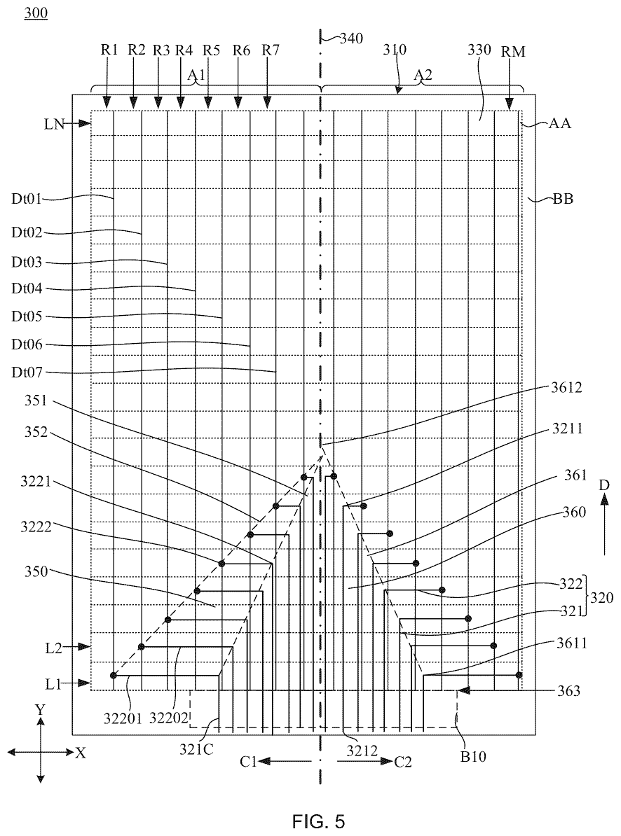

In some embodiments, as shown in FIG. 5, a minimum closed graphic region where all second sub-lines 322, located on a same side of the center line 340 of the display area AA in the second direction X, are located is a first wiring region 350. Referring to FIG. 5, an end of a second sub-line 322 connected to a first sub-line 321 is a third end 3221, and another end of the second sub-line 322 away from the first sub-line 321 is a fourth end 3222. The first wiring region 350 includes a first edge 351 and a second edge 352. The first edge 351 passes through third ends 3221 of multiple second sub-lines 322. The second edge 352 passes through fourth ends 3222 of multiple second sub-lines 322.

It will be noted that the first edge 351 is a straight line. In some examples, in a display sub-region, the first edge 351 may pass through third ends 3221 of all the second sub-lines 322. In some other examples, the first edge 351 may be a fitted straight line of the third ends 3221 of all the second sub-lines 322. In this case, in the display sub-region, the first edge 351 may pass through only third ends 3221 of some of all the second sub-lines 322, and third ends 3221, that the first edge 351 not passes through, of remaining second sub-lines 322 may be distributed on two sides of the first edge 351; alternatively, in the display sub-region, the third ends 3221 of all the second sub-lines 322 are distributed on the two sides of the first edge 351.

Similarly, the second edge 352 is a straight line. In some examples, in a display sub-region, the second edge 352 may pass through fourth ends 3222 of all the second sub-lines 322. In some other examples, the second edge 352 may be a fitted straight line of the fourth ends 3222 of all the second sub-lines 322. In this case, in the display sub-region, the second edge 352 may pass through only fourth ends 3222 of some of all the second sub-lines 322, and fourth ends 3222, that the second edge 352 not passes through, of remaining second sub-lines 322 may be distributed on two sides of the second edge 352; alternatively, in the display sub-region, the fourth ends 3222 of all the second sub-lines 322 are distributed on the two sides of the second edge 352.

The first edge 351 and the second edge 352 may intersect at a point, and two ends of the second sub-line 32201 the closest to the lead-out region B10 may respectively intersect the first edge 351 and the second edge 352. The first edge 351, the second edge 352 and the second sub-line 32201 that is the closest to the lead-out region B10 may enclose the first wiring region 350.

In some examples, the two sides of the center line 340, in the second direction X, of the display area AA are each provided with a first wiring region 350.

For example, referring to FIG. 5, the first wiring region 350 may be an obtuse triangle region.

In some other examples, the closer a first sub-line 321 is to the center line 340 of the display area AA in the second direction X, the farther a second sub-line 322 to which the first sub-line 321 is connected is away from the lead-out region B10; the farther a second sub-line 322 is away from the lead-out region B10, the farther a data line Dt to which the second sub-line 322 is connected is away from the center line 340 of the display area AA in the second direction X. In this case, the first wiring region 350 is an acute triangle region.

The first wiring region 350 where the second sub-lines 322 are located is described in some of the above embodiments, and a second wiring region 360 where first sub-lines 321 are located will be described below.

In some embodiments, as shown in FIG. 5, a minimum closed graphic region, in which all first sub-lines 321 located on a same side of the center line 340, in the second direction X, of the display area AA are located, is a second wiring region 360.

For example, referring to FIG. 5, an end of a first sub-line 321 connected to a second sub-line 322 is a first end 3211; the second wiring region 360 includes a third edge 361. In a display sub-region, the third edge 361 passes through first ends 3211 of multiple first sub-lines 321. It will be noted that, in the display sub-region, the third edge 361 may pass through only first ends 3211 of some of all the first sub-lines 321. In this case, the third edge 361 may be a fitted straight line of first ends 3221 of all the first sub-lines 321. The first ends 3211 of the first sub-lines 321 are connected to the third ends 3221 of the respective second sub-lines 322, so that the third edge 361 coincides with the first edge 351.

The third edge 361 includes a fifth end 3611 and a sixth end 3612 that are opposite to each other, the fifth end 3611 is connected to the first sub-line 321 the farthest away from the center line 340, and the sixth end 3612 intersects the center line 340.

The third edge 361, the center line 340, the first sub-line 321 the farthest away from the center line 340 and a partial edge 363 of the display area AA may enclose the second wiring region 360.

For example, referring to FIG. 5, the second wiring region 360 is a right trapezoid region.

In some embodiments, referring to FIGS. 7 to 10, the obtuse triangle region has two obtuse angle edges, an obtuse angle edge, with a relatively large length, coincides with an oblique edge of the right trapezoid region, and the length of the obtuse angle edge, with the relatively large length, is equal to a length of the oblique edge of the right trapezoid region.

For example, the two obtuse angle edges of the obtuse triangle region are the first edge 351 and the second sub-line 322 that is the closest to the lead-out region B10, a length of the first edge 351 is greater than a length of the second sub-line 322 the closest to the lead-out region B10, and thus the obtuse angle edge, with the relatively large length, of the obtuse triangle region is the first edge 351. The third edge 361 is the oblique edge of the right trapezoid region, and the third edge 361 and the first edge 351 coincide with each other and have a same length.

An arrangement manner of the jumper wires Dtb will be described below with reference to the first wiring region 350 and the second wiring region 360.

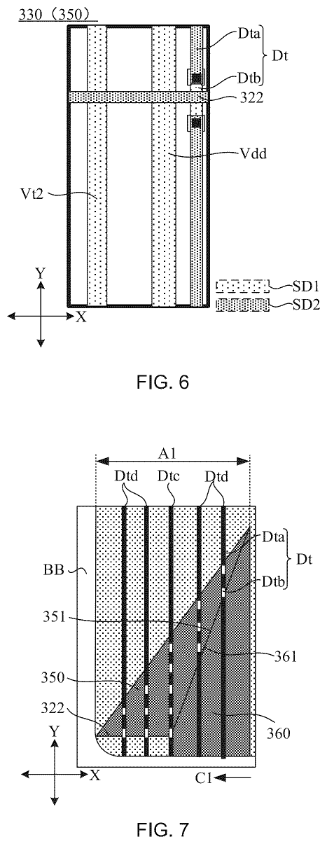

In some embodiments, as shown in FIGS. 6 to 10, at least a portion, located within the first wiring region 350, of each data line Dt passing through the first wiring region 350 is provided with jumper wire(s) Dtb.

In some examples, only the portion, located within the first wiring region 350, of each data line Dt passing through the first wiring region 350 is provided with the jumper wire(s) Dtb, so that the number of jumper wires Dtb provided in each data line Dt is relatively small. As a result, each data line Dt has relatively small loading.

For example, referring to FIG. 7, of each data line Dt passing through the first wiring region 350, only the portion located within the first wiring region 350 is provided with jumper wires Dtb, and portions located outside the first wiring region 350 are each a main line Dta.

For example, except for a designated sub-pixel region, a data line Dt is provided with a jumper wire Dtb at each portion passing through a sub-pixel region 330. An orthographic projection, on the substrate 310, of the data line Dt and an orthographic projection, on the substrate 310, of a second sub-line 322 corresponding to the data line Dt intersect in the designated sub-pixel region, and the orthographic projection, on the substrate 310, of the data line Dt and an orthographic projection, on the substrate 310, of a second sub-line 322 not corresponding to the data line Dt may intersect in another sub-pixel region other than the designated sub-pixel region. In addition, it will be noted that a dimension, in the first direction Y, of a jumper wire Dtb is less than a dimension, in the first direction Y, of a sub-pixel region 330. That is, the jumper wire Dtb cannot pass through the entire sub-pixel region 330.

In some embodiments, the direction from the center line 340, in the second direction X, of the display area AA to any side, in the second direction X, of the display area AA is the first setting direction; numbers of jumper wires Dtb respectively included in all data lines Dt firstly increase and then decrease in the first setting direction.

Referring to FIG. 7, FIG. 7 shows a wiring manner in the first region A1 in some embodiments; in the first region A1, the numbers of jumper wires Dtb respectively included in all the data lines Dt firstly increase and then decrease in the first setting direction C1.

In some examples, referring to FIGS. 2A, 2B and 5, in a display sub-region, the numbers of second sub-lines 322 that the data lines Dt sequentially arranged in the first setting direction respectively crosses firstly increase and then decrease. For example, the jumper wires Dtb may be disposed only in the first wiring region 350, so that the number of jumper wires Dtb disposed in a data line Dt is equal to the number of second sub-lines 322 that the data line Dt crosses. In this case, the numbers of jumper wires Dtb respectively disposed in the data lines Dt passing through the first wiring region 350 firstly increase and then decrease in the first setting direction.

The above embodiments will be described by considering the first region A1 as an example. Referring to FIG. 5, in the first region A1, a data line Dt07 to which the seventh column R7 of sub-pixel regions correspond crosses one second sub-line 322, and correspondingly, the data line Dt07 may be provided with one jumper wire Dtb therein; a data line Dt06 to which the sixth column R6 of sub-pixel regions correspond crosses two second sub-lines 322, and correspondingly, the data line Dt06 may be provided with two jumper wires Dtb therein; a data line Dt05 to which the fifth column R5 of sub-pixel regions correspond crosses three second sub-lines 322, and correspondingly, the data line Dt05 may be provided with three jumper wires Dtb therein.

A data line Dt04 to which the fourth column R4 of sub-pixel regions correspond crosses three second sub-lines 322, and correspondingly, the data line Dt04 may be provided with three jumper wires Dtb therein; the data line Dt03 to which the third column R3 of sub-pixel regions correspond may cross the second sub-line 32201 to which the first row L1 of sub-pixel regions correspond and the second sub-line 32202 to which the second row L2 of sub-pixel regions correspond (that is, the data line Dt03 to which the third column R3 of sub-pixel regions correspond may cross two second sub-lines 322), and correspondingly, the data line Dt03 is provided with two jumper wires Dtb therein; the data line Dt02 to which the second column R2 of sub-pixel regions correspond may cross the second sub-line 32201 to which the first row L1 of sub-pixel regions correspond (that is, the data line Dt02 to which the second column R2 of sub-pixel regions correspond may cross one second sub-line 322), and correspondingly, the data line Dt02 is provided with one jumper wire Dtb therein; the data line Dt01 to which the first column R1 of sub-pixel regions correspond does not cross any one second sub-line 322, and correspondingly, the data line Dt01 is provided with no jumper wire Dtb therein.

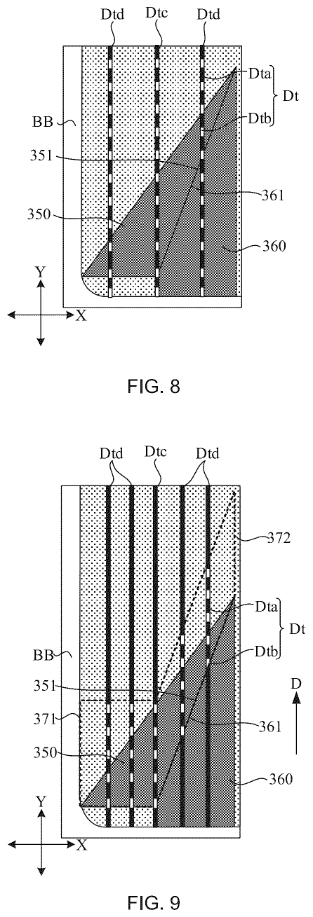

In some embodiments, the jumper wires Dtb may be disposed only in the first wiring region 350. In some other embodiments, referring to FIGS. 8 to 10, of each data line Dt passing through the first wiring region 350, not only the portion located within the first wiring region 350 is provided with the jumper wires Dtb, but also the portion located outside the first wiring region 350 is provided with the jumper wires Dtb. For example, the number of jumper wires Dtb in each data line Dt passing through the first wiring region 350 may be equal, so that the loading of each data line Dt is the same. In this example, referring to FIG. 3A, in addition to a position where the data line Dt passes through a second sub-line 322, the data line Dt may be further provided with a jumper wire Dtb at another position.

In some embodiments, referring to FIGS. 7 to 10, of all the data lines Dt passing through the first wiring region 350, a data line of which a portion located within the first wiring region 350 has the greatest number of jumper wires Dtb is a first-type data line Dtc, and data lines other than the first-type data line Dtc are second-type data lines Dtd.

The number of jumper wires Dtb included in the portion, located within the first wiring region 350, of the first-type data line Dtc is greater than the number of jumper wires Dtb included in a portion, located within the first wiring region 350, of each second-type data line Dtd.

For example, referring to FIG. 5, in the first region A1, the first sub-line 321 the farthest away from the center line 340 is a designated first sub-line 321C. In the plurality of data lines Dt, two data lines Dt (i.e., the data line Dt04 and the data line Dt05) adjacent to the designated first sub-line 321C each pass through the first wiring region 350 and cross the greatest number of second sub-lines 322, which means that portions, located within the first wiring region 350, of the two data lines Dt adjacent to the designated first sub-line 321C each have the greatest number of jumper wires Dtb, so that the two data lines Dt adjacent to the designated first sub-line 321C are each the first-type data line Dtc.

In some embodiments, referring to FIGS. 8 to 10, a portion, located outside the first wiring region 350, of each second-type data line Dtd is provided with jumper wire(s) Dtb. The number of jumper wires Dtb included in each second-type data line Dtd is equal to the number of jumper wires Dtb included in the first-type data line Dtc. Thus, the number of jumper wires Dtb in each data line Dt passing through the first wiring region 350 is equal, so that the loading of each data line Dt passing through the first wiring region 350 is the same.

In some embodiments, referring to FIG. 5, the end of the first sub-line 321 connected to the respective second sub-line 322 is the first end 3211, and the other end of the first sub-line 321 is a second end 3212; a direction from the second end 3212 to the first end 3211 is a second setting direction D. The direction represented by the arrow D is the second setting direction.

Referring to FIG. 9, of each second-type data line Dtd, the jumper wires Dtb located within the first wiring region 350 and the jumper wires Dtb located outside the first wiring region 350 are arranged in the second setting direction D. The jumper wires Dtb located outside the first wiring region 350 are all located on a side of the first wiring region 350 away from the lead-out region B10.

In some examples, referring to FIG. 9, only the portion, located within the first wiring region 350, of the first-type data line Dtc is provided with jumper wires Dtb; the portion, located within the first wiring region 350, of the second-type data line Dtd is provided with jumper wires Dtb, and the portion, located outside the first wiring region 350, of the second-type data line Dtd is also provided with jumper wires Dtb.

For example, the number of second sub-lines 322 that the first-type data line Dtc crosses is equal to the number of jumper wires Dtb in the first-type data line Dtc. The number of second sub-lines 322 that the second-type data line Dtd crosses is less than the number of second sub-lines 322 that the first-type data line Dtc crosses. In this way, after the second-type data line Dtd passes through the first wiring region 350 in the first direction Y, every time the second-type data line Dtd passes through a sub-pixel region 330, a jumper wire Dtb is provided, until the number of jumper wires Dtb in the second-type data line Dtd is equal to the number of jumper wires Dtb in the first-type data line Dtc.

In some examples, referring to FIG. 9, a rectangular region 371 is defined by taking the second sub-line 322 the closest to the lead-out region B10 and a portion, passing through the first wiring region 350, of a straight line on which the designated first sub-line 321C is located as two adjacent edges; jumper wires Dtb of data lines Dt passing through the rectangular region 371 are all disposed in the rectangular region 371. In the rectangular region 371, except for a designated sub-pixel region, a data line Dt is provided with a jumper wire Dtb at each portion passing through a sub-pixel region 330. It will be noted that a dimension, in the first direction Y, of a jumper wire Dtb is less than a dimension, in the first direction Y, of a sub-pixel region 330, and the jumper wire Dtb cannot pass through the entire sub-pixel region 330.

A parallelogram region 372 is defined by taking the first edge 351 and a portion, passing through the first wiring region 350, of a straight line on which a designated second sub-line 322C is located as two adjacent edges; jumper wires Dtb of data lines Dt passing through the parallelogram region 372 are all disposed in the parallelogram region 372. In the parallelogram region 372, except for a designated sub-pixel region, a data line Dt is provided with a jumper wire Dtb at each portion passing through a sub-pixel region 330. The number of jumper wires Dtb in each data line Dt passing through the rectangular region 371 is equal to the number of jumper wires Dtb in each data line Dt passing through the parallelogram region 372.

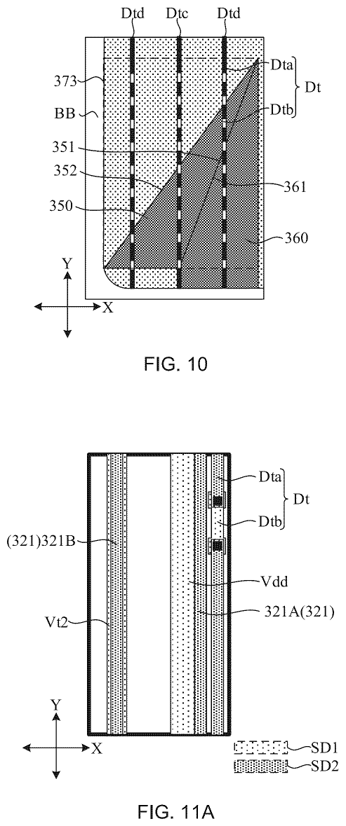

In addition to the above examples, in some other embodiments, referring to FIGS. 8 and 10, a portion, located outside the first wiring region 350, of each data line Dt passing through the first wiring region 350 is provided with jumper wires Dtb; the number of jumper wires Dtb in each data line Dt is equal. Jumper wires Dtb included in all the data lines Dt passing through the first wiring region 350 are arranged in rows in the first direction Y. The number of jumper wires Dtb in each data line Dt is equal, so that the loading of each data line Dt is the same.

For example, the data lines Dt passing through the first wiring region 350 include the first-type data line(s) Dtc and the second-type data lines Dtd; in each of the first-type data line(s) Dtc and the second-type data lines Dtd, the portion located within the first wiring region 350 and the portion located outside the first wiring region 350 are each provided with jumper wires Dtb.

Firstly, it will be understood that a second sub-line 322 and a data line Dt that are electrically connected to each other correspond to each other, and the data line Dt and the second sub-line 322 corresponding to each other intersect at a designated sub-pixel region. In some embodiments, the second sub-line 322 is electrically connected to a main line Dta of the data line Dt corresponding to the second sub-line 322. For example, the data line Dt and the respective second sub-line 322 intersect at the designated sub-pixel region, and the second sub-line 322 is electrically connected to the main line Dta of the respective data line Dt. Thus, the data line Dt is provided with no jumper wire Dtb at a portion passing through the designated sub-pixel region corresponding to the data line Dt. That is, the portion of the data line Dt passing through the designated sub-pixel region 330 is the main line Dta.

In some examples, referring to FIG. 8, as for each data line Dt, every time the data line Dt passes through a sub-pixel region 330 except for a respective designated sub-pixel region 330 (which is not shown in FIG. 8 and may refer to the sub-pixel region 330 in FIG. 6), a jumper wire Dtb is provided. It will be noted that a dimension, in the first direction Y, of a jumper wire Dtb is less than a dimension, in the first direction Y, of a sub-pixel region 330. That is, the jumper wire Dtb cannot pass through the entire sub-pixel region 330. For example, there are N sub-pixel regions 330 in a column of sub-pixels, a data line Dt passes through the N sub-pixel regions 330, and thus there are (N-1) jumper wires Dtb disposed in the data line Dt. In this case, the jumper wires Dtb of the plurality of data lines Dt may be arranged in rows in the second direction X.

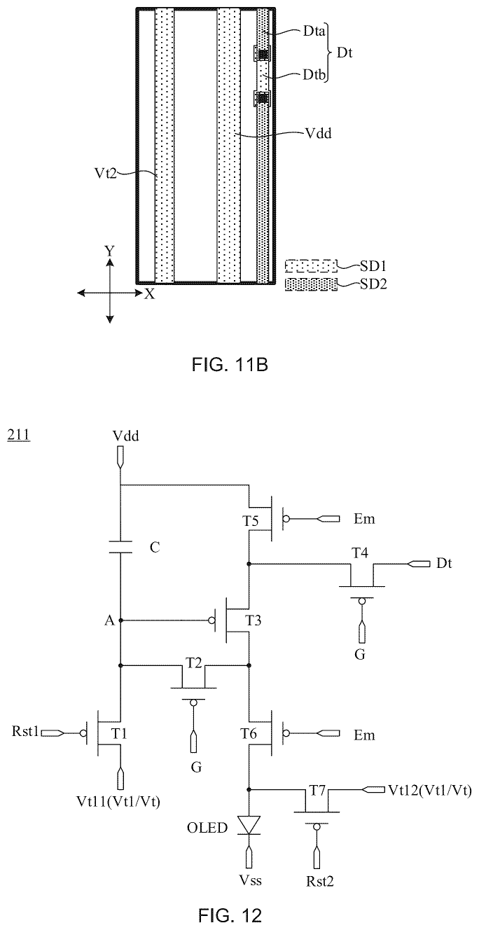

In these embodiments, all sub-pixel regions 330, except for designated sub-pixel regions 330 respectively corresponding to all the data lines Dt, are each provided with a jumper wire Dtb therein. In this case, referring to FIG. 11A, a sub-pixel region 330 located in the second wiring region 360 is provided with main lines Dta, a jumper wire Dtb and a first sub-line 321 therein, but is provided with no second sub-line therein. Referring to FIG. 11B, a sub-pixel region 330 located outside both the first wiring region 350 and the second wiring region 360 is provided with main lines Dta and a jumper wire Dtb therein, but is provided with no first sub-line and no second sub-line therein.

In some other embodiments, a sub-pixel region 330 located outside both the first wiring region 350 and the second wiring region 360 may be provided with a first sub-line and a second sub-line therein. The first sub-line and the second sub-line that in the sub-pixel region 330 located outside both the first wiring region 350 and the second wiring region 360 each serve as a dummy line, which is electrically connected to a first power supply signal line Vdd or a second power supply signal line Vss instead of being electrically connected to a data line Dt, so as to reduce a voltage drop of a signal on the first power supply signal line Vdd or the second power supply signal line Vss. Moreover, it is possible to avoid accumulation of static electricity generated by the first sub-line and the second sub-line that each serving as the dummy line.

In addition to the above embodiments, in some other embodiments, referring to FIG. 10, the display area AA includes a rectangular region 373, the second edge 352 is a diagonal of the rectangular region 373, and an edge of the rectangular region 373 passes through the second sub-line 322 the closest to the lead-out region B10. In the rectangular region 373, a data line Dt is provided with a jumper wire Dtb at each portion passing through a sub-pixel region except for a designated sub-pixel region, so that the number of jumper wires Dtb in each data line Dt is equal.

For example, the second sub-line 322 the closest to the lead-out region B10 corresponds to an n-th row of sub-pixel regions, where n is greater than or equal to 1; the first sub-line 321 with the maximum dimension in the first direction Y passes through N/2 rows of sub-pixel regions. In this case, every time a portion, passing through from the n-th row of sub-pixel regions to a (n+N/2)-th row of sub-pixel regions, of a data line Dt passes through a sub-pixel region 330 except for a designated sub-pixel region corresponding to the data line Dt, a jumper wire Dtb may be provided. As a result, there are (N/2-1) jumper wires Dtb disposed in each data line Dt.

In some embodiments, there are multiple rows of sub-pixel regions between the second sub-line 322 the closest to the lead-out region B10 and the lead-out region B10, and there is no jumper wire Dtb disposed in the multiple rows of sub-pixel regions located between the second sub-line 322 the closest to the lead-out region B10 and the lead-out region B10.

The wiring manner of the fan-out lines 320 in the array substrate 300 is described above, and the pixel driving circuits included in the array substrate 300 will be described below.

In some embodiments, the array substrate 300 includes the plurality of pixel driving circuits 211, and each pixel driving circuit 211 includes a plurality of transistors. In some embodiments, a structure of the pixel driving circuit in the embodiments of the present disclosure varies, which may be set according to actual needs. For example, the structure of the pixel driving circuit may include “2T1C”, “6T1C”, “7T1C”, “6T2C” or “7T2C”. Here, “T” represents a thin film transistor, the number before the “T” represents the number of thin film transistors; “C” represents a storage capacitor C, and the number before the “C” represents the number of storage capacitors C. Hereinafter, the description will be introduced by considering the pixel driving circuit with the structure of “7T1C” as an example.

Referring to FIG. 12, the pixel driving circuit 211 may include a first transistor T1, a second transistor T2, a third transistor T3, a fourth transistor T4, a fifth transistor T5, a sixth transistor T6, a seventh transistor T7 and a capacitor C. Signal lines electrically connected to the pixel driving circuit 211 include a gate scanning signal line G, a first reset signal line Rst1, a second reset signal line Rst2 and a light-emitting control signal line Em.

A gate of the first transistor T1 is electrically connected to the first reset signal line Rst1, a first electrode of the first transistor T1 is electrically connected to an initial signal line Vt, and a second electrode of the first transistor T1 is electrically connected to a driving node A; a gate of the second transistor T2 is electrically connected to the gate scanning signal line G, a first electrode of the second transistor T2 is electrically connected to a second electrode of the third transistor T3, and a second electrode of the second transistor T2 is electrically connected to the driving node A; a gate of the third transistor T3 is electrically connected to the driving node A; a gate of the fourth transistor T4 is electrically connected to the gate scanning signal line G, a first electrode of the fourth transistor T4 is electrically connected to a data line Dt, and a second electrode of the fourth transistor T4 is electrically connected to a first electrode of the third transistor T3; a gate of the fifth transistor T5 and a gate of the sixth transistor T6 are both electrically connected to the light-emitting control signal line Em, a first electrode of the fifth transistor T5 is electrically connected to a first power supply signal line Vdd, a second electrode of the fifth transistor T5 is electrically connected to the first electrode of the third transistor T3, a first electrode of the sixth transistor T6 is electrically connected to the second electrode of the third transistor T3, and a second electrode of the sixth transistor T6 is electrically connected to an anode of a light-emitting device OLED; a gate of the seventh transistor T7 is electrically connected to the second reset signal line Rst2, a first electrode of the seventh transistor T7 is electrically connected to another initial signal line Vt, a second electrode of the seventh transistor T7 is electrically connected to the anode of the light-emitting device OLED, and a cathode of the light-emitting device OLED is electrically connected to a second power supply signal line Vss.

In some embodiments, the initial signal lines Vt connected to the same pixel driving circuit 211 include two first initial signal lines Vt1. For convenience of distinction, referring to FIG. 12, a first initial signal line Vt1 electrically connected to the first electrode of the first transistor T1 may be defined as a first initial signal sub-line Vt11, and another first initial signal line Vt1 electrically connected to the first electrode of the seventh transistor T7 is defined as a second initial signal sub-line Vt12.

In some embodiments, all the transistors in the pixel driving circuit 211 may be each a P-type transistor, and the P-type transistor is turned on when a gate thereof receives a low-voltage signal. In some other embodiments, all the transistors in the pixel driving circuit 211 may be each an N-type transistor, and the N-type transistor is turned on when a gate thereof receives a high-voltage signal. In addition, in yet other embodiments, some transistors in the pixel driving circuit 211 are each the N-type transistor, and the remaining transistors are each the P-type transistor. For example, the first transistor T1 and the second transistor T2 are each the N-type transistor, and the remaining transistors are each the P-type transistor. It will be noted that “the high-voltage signal” and “the low-voltage signal” are popular expressions. In general, a turn-on condition of the N-type transistor is that a gate-source voltage difference is greater than a threshold voltage of the N-type transistor (that is, a gate voltage of the N-type transistor is greater than a sum of a source voltage of the N-type transistor and the threshold voltage of the N-type transistor), and the threshold voltage of the N-type transistor is a positive value, and thus a gate voltage signal enabling the N-type transistor to be turned on is referred to as the high-voltage signal; a turn-on condition of the P-type transistor is that an absolute value of a gate-source voltage difference is greater than a threshold voltage of the P-type transistor, and the threshold voltage of the P-type transistor is a negative value (that is, a gate voltage of the P-type transistor is less than a sum of a source voltage of the P-type transistor and the threshold voltage of the P-type transistor), and thus a gate voltage signal enabling the P-type transistor to be turned on is referred to as the low-voltage signal. The phrases “high” and “low” of “the high-voltage signal” and “the low-voltage signal” are described relative to a reference voltage (e.g., 0V).

Film layer structures in the array substrate 300 provided in some embodiments of the present disclosure will be described based on the pixel driving circuit 211 disclosed in the above embodiments.

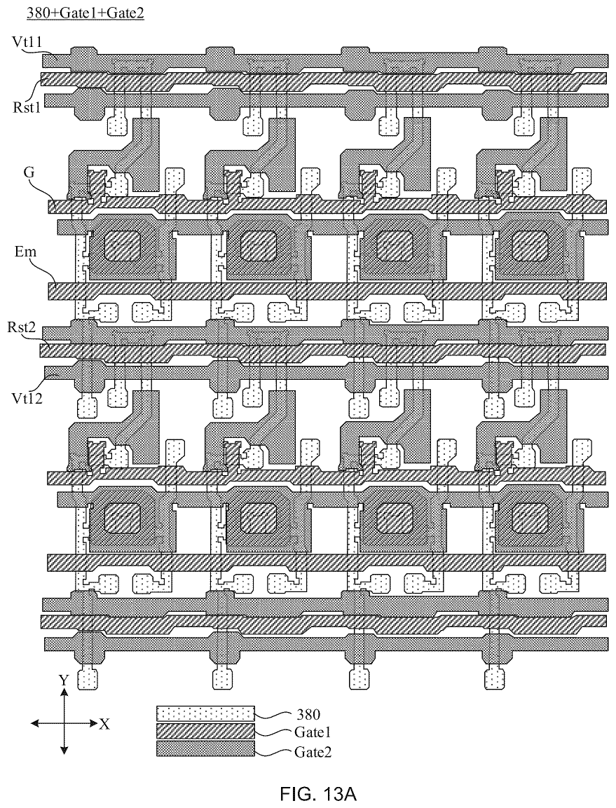

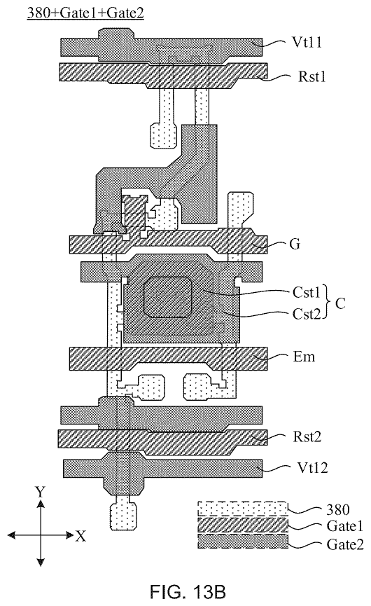

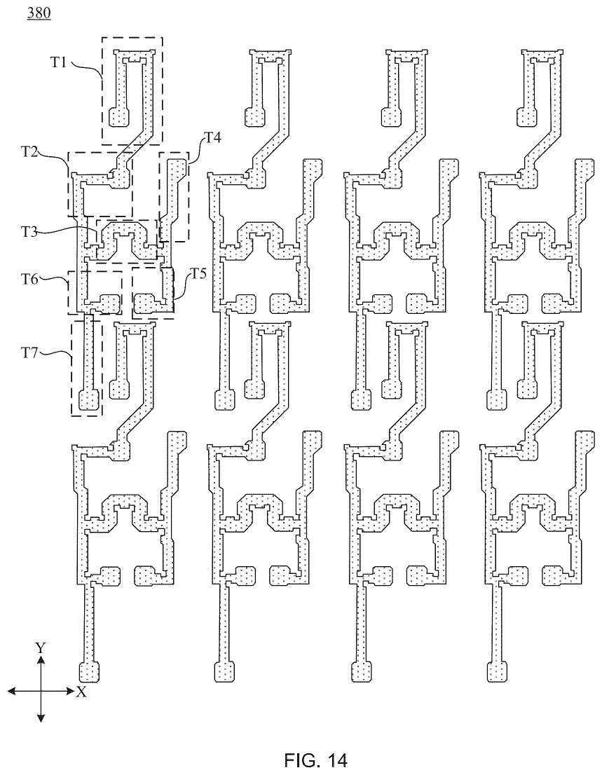

In some embodiments, referring to FIGS. 13A and 13B, the array substrate 300 includes the active film layer 380, the first gate metal layer Gate1 and the second gate metal layer Gate2 that are sequentially arranged on the substrate 310. The active film layer 380 includes active layers of the plurality of transistors in the pixel driving circuit 211, and an active layer of each transistor includes a first electrode region, a second electrode region and a channel region that connects the first electrode region and the second electrode region. Referring to FIG. 14, FIG. 14 shows a structure of the active film layer 380 and a position of the active layer of each transistor in the active film layer 380.

The first gate metal layer Gate1 and the second gate metal layer Gate2 will be described below with reference to the active film layer 380.

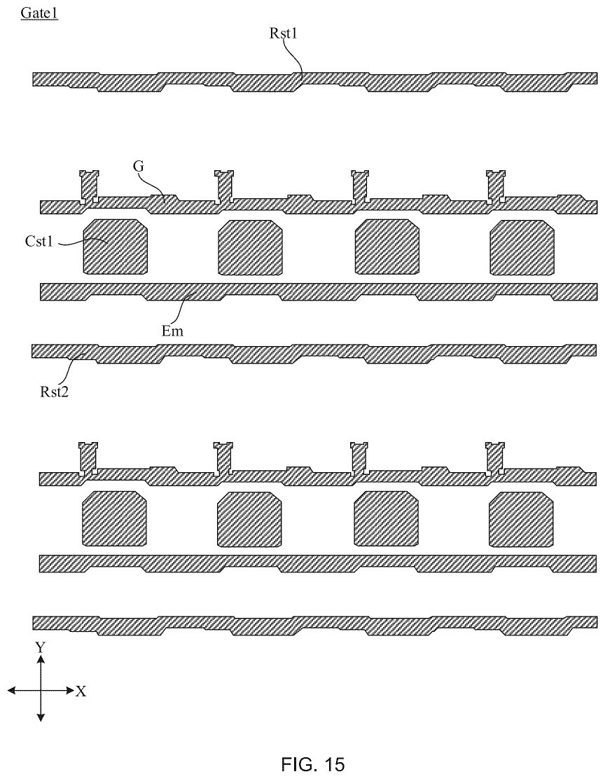

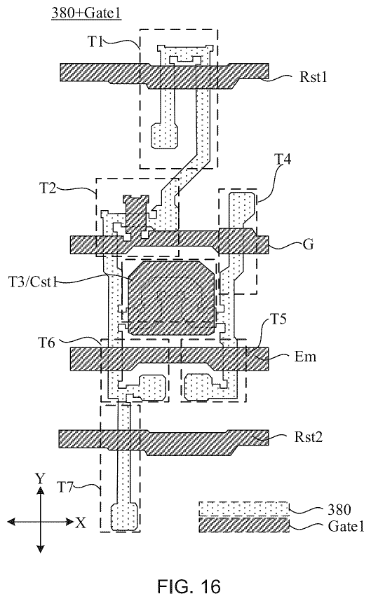

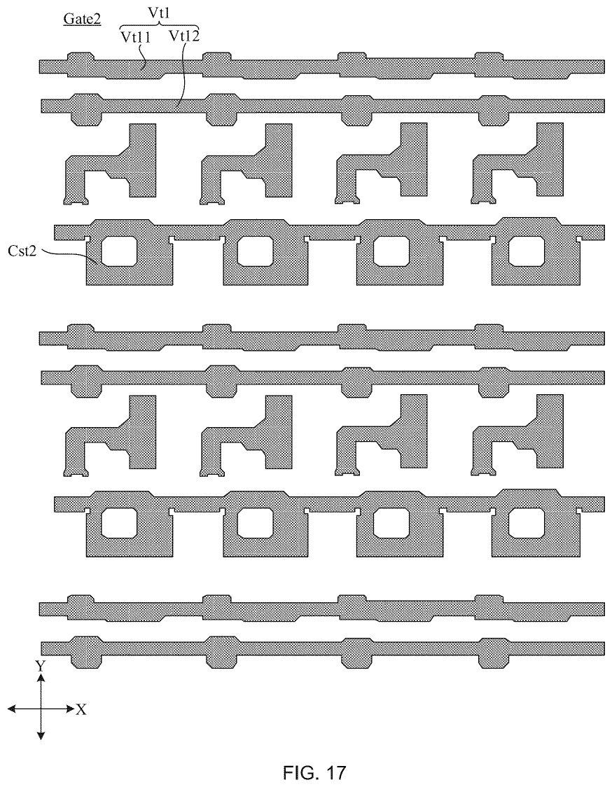

Referring to FIGS. 15 and 16, the first gate metal layer Gate1 includes the second reset signal line Rst2, the light-emitting control signal line Em, the gate scanning signal line G and the first reset signal line Rst1 that are sequentially arranged in the first direction Y, and the second reset signal line Rst2, the light-emitting control signal line Em, the gate scanning signal line G and the first reset signal line Rst1 each extend in the second direction X.

A portion, passing through a channel region of a respective transistor, of each of the above signal lines may serve as a gate of the respective transistor. Referring to FIG. 16, the gate of the first transistor T1 is located in the first reset signal line Rst1, and a portion, passing through the channel region of the first transistor T1, of the first reset signal line Rst1 serves as the gate of the first transistor T1.

Referring to FIG. 16, the gate of the second transistor T2 and the gate of the fourth transistor T4 are located in the gate scanning signal line G; in a sub-pixel region 330, the gate scanning signal line G sequentially passes through the channel region of the second transistor T2 and the channel region of the fourth transistor T4 in the second direction X; of the gate scanning signal line G, a portion passing through the channel region of the second transistor T2 and a portion passing through the channel region of the fourth transistor T4 serve as the gate of the second transistor T2 and the gate of the fourth transistor T4, respectively.

Referring to FIG. 16, the gate of the sixth transistor T6 and the gate of the fifth transistor T5 are located in the light-emitting control signal line Em; in the sub-pixel region 330, the light-emitting control signal line Em sequentially passes through the channel region of the sixth transistor T6 and the channel region of the fifth transistor T5 in the second direction X; a portion, passing through the channel region of the sixth transistor T6, of the light-emitting control signal line Em serves as the gate of the sixth transistor T6, and a portion, passing through the channel region of the fifth transistor T5, of the light-emitting control signal line Em serves as the gate of the fifth transistor T5.

Referring to FIG. 16, the gate of the seventh transistor T7 is located in the second reset signal line Rst2, and a portion, passing through the channel region of the seventh transistor T7, of the second reset signal line Rst2 serves as the gate of the seventh transistor T7.

It will be noted that the active layers of the plurality of pixel driving circuits 211 are arranged in an array on the substrate 310, and a row of pixel driving circuits 211 correspond to a second reset signal line Rst2, a light-emitting control signal line Em, a gate scanning signal line G and a first reset signal line Rst1.

In addition to the above signal lines, referring to FIGS. 15 and 16, a first plate Cst1 of the capacitor C is formed in the first gate metal layer Gate1, and a portion of the first plate Cst1 overlapping with the channel region of the third transistor T3 serves as the gate of the third transistor T3.

The first gate metal layer Gate1 is described above, and the second gate metal layer Gate2 will be described below.

Referring to FIG. 17, a plurality of first initial signal lines Vt1 are formed in the second gate metal layer Gate2, and the plurality of first initial signal lines Vt1 each extend in the second direction X and are sequentially arranged in the first direction Y. Every two first initial signal lines Vt1 pass through a same row of sub-pixel regions, and a row of pixel driving circuits 211 may be electrically connected to two first initial signal lines Vt1. The two first initial signal lines Vt1 electrically connected to the row of pixel driving circuits 211 are the first initial signal sub-line Vt11 and the second initial signal sub-line Vt12. The first initial signal sub-line Vt11 is electrically connected to the first electrode of the first transistor T1, and the second initial signal sub-line Vt12 is electrically connected to the first electrode of the seventh transistor T7.

In addition, referring to FIG. 17, a second plate Cst2 of the capacitor C is formed in the second gate metal layer Gate2. Referring to FIG. 13B, of the capacitor C, an orthographic projection of the first plate Cst1 on the substrate 310 overlaps with an orthographic projection of the second plate Cst2 on the substrate 310. The second plate Cst2 may be electrically connected to the first power supply signal line Vdd, so that a first power supply signal transmitted from the first power supply signal line Vdd may be transmitted to the second plate Cst2. The first power supply signal is a constant voltage signal, so that voltages of second plates Cst2 in all the pixel driving circuits 211 are equal to one another. Therefore, referring to FIG. 17, the second plates Cst2 in all the pixel driving circuits 211 may be electrically connected to one another.

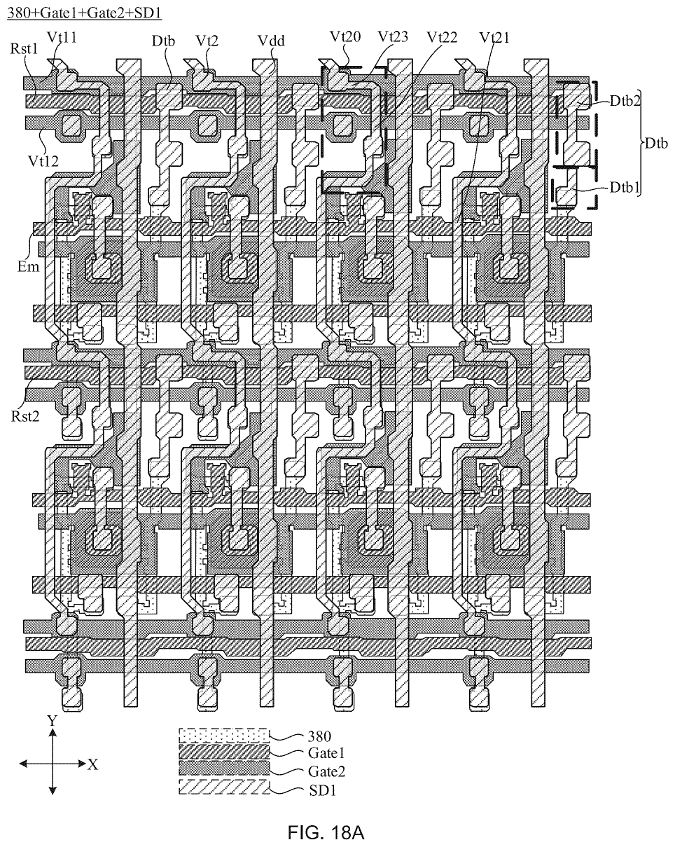

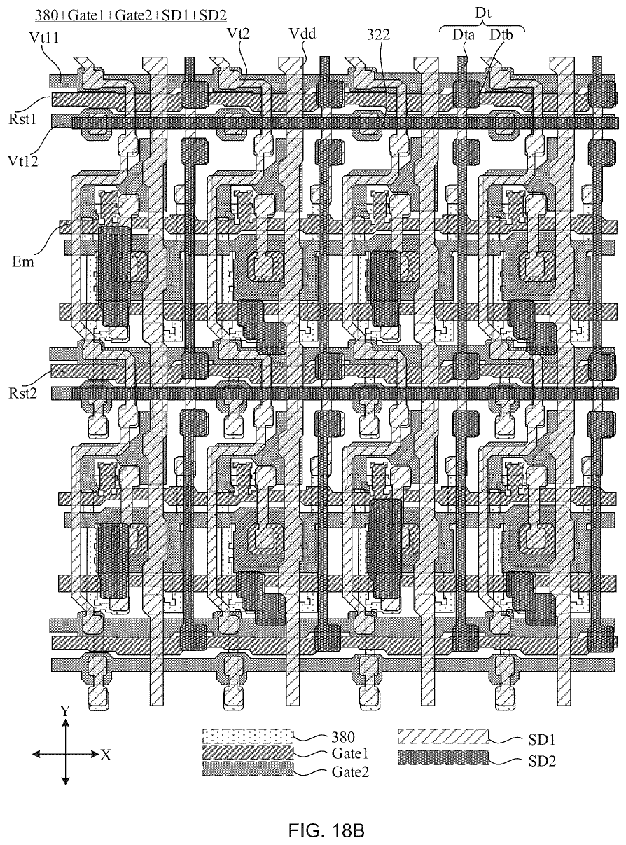

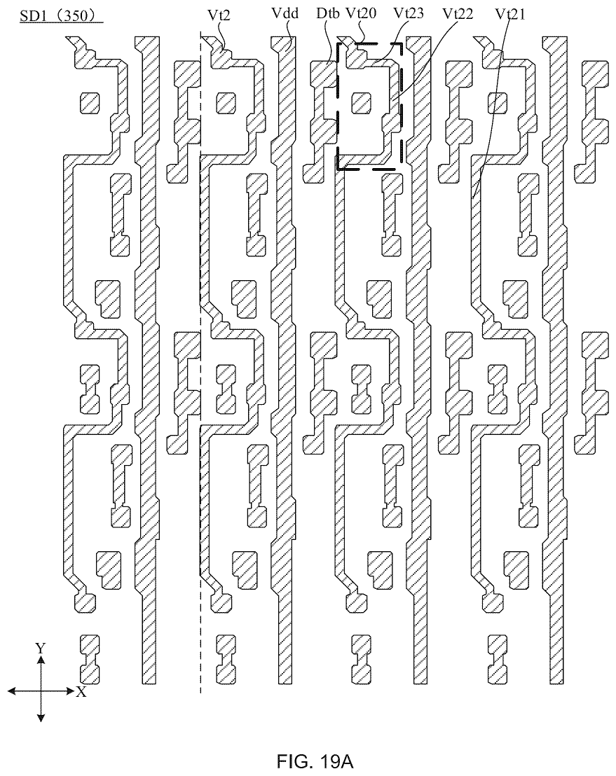

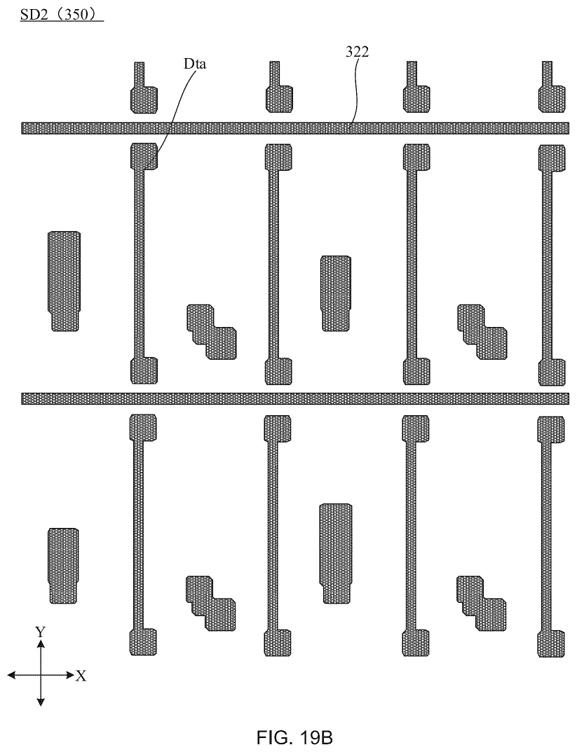

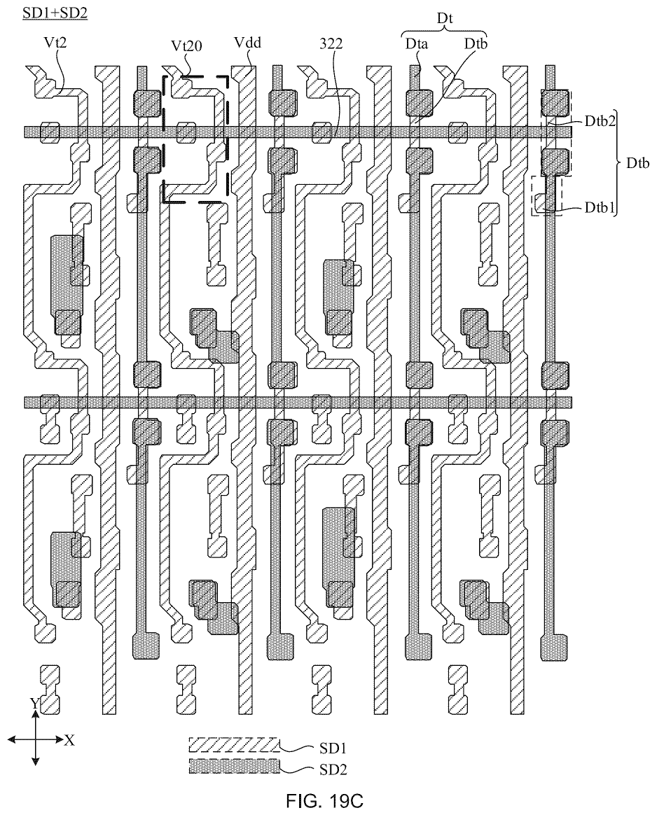

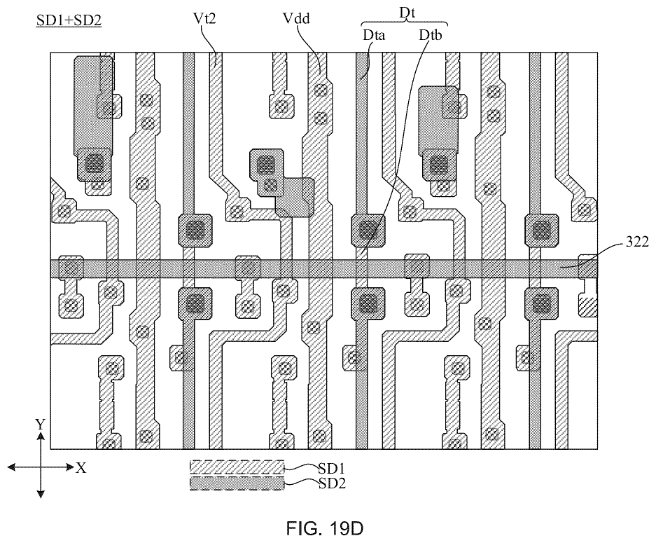

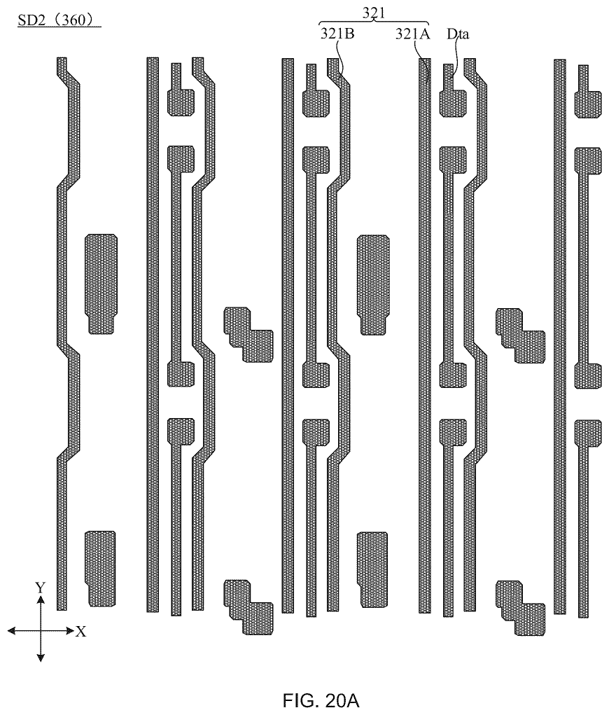

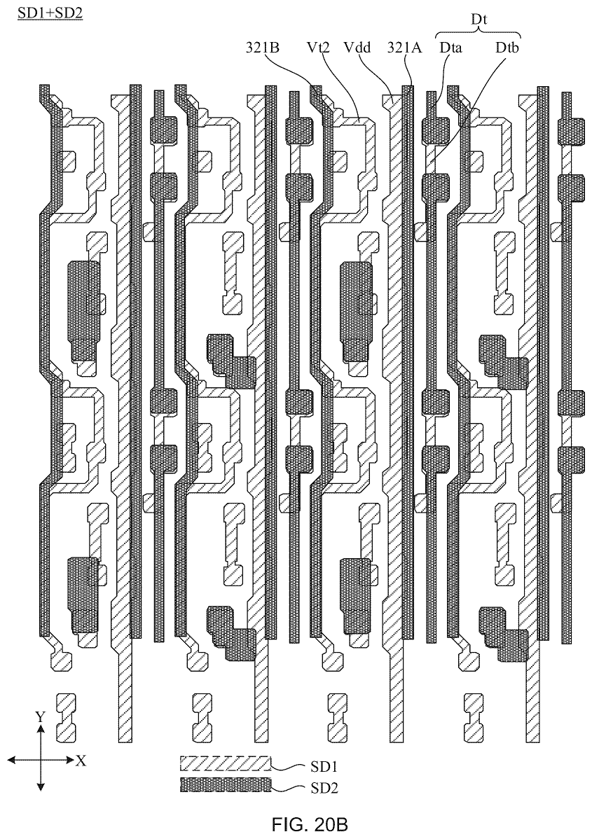

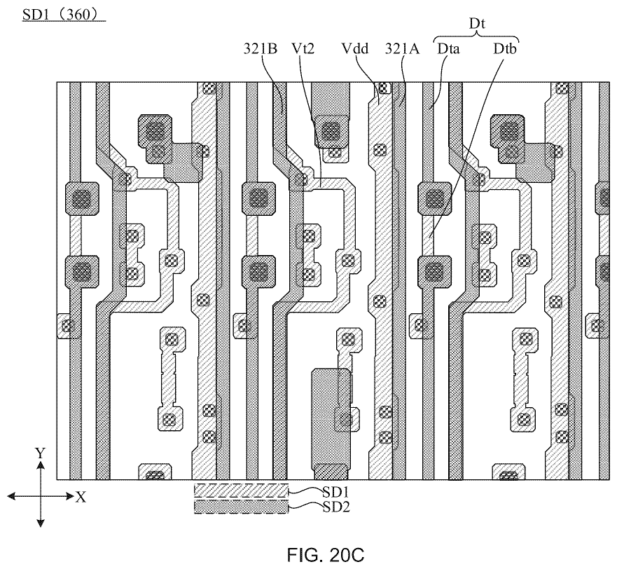

Based on the film layer structures in the array substrate 300 provided in the above embodiments, in some embodiments, referring to FIGS. 18A and 18B, the array substrate 300 further includes the first source-drain metal layer SD1 located on the first side of the substrate 310 and the second source-drain metal layer SD2 located on a side of the first source-drain metal layer SD1 away from the substrate 310. Referring to FIG. 19A, the first power supply signal lines Vdd and the jumper wires Dtb are located in the first source-drain metal layer SD1. Referring to FIGS. 19B and 20A, the first sub-lines 321, the second sub-lines 322 and the main lines Dta are located in the second source-drain metal layer SD2.

Firstly, the first source-drain metal layer SD1 and the second source-drain metal layer SD2 that are in the first wiring region 350 will be described.

For example, referring to FIG. 19A, in the first wiring region 350, first power supply signal lines Vdd are disposed in the first source-drain metal layer SD1, and the first power supply signal lines Vdd each extend in the first direction Y and are sequentially arranged in the second direction X. A first power supply signal line Vdd corresponds to a column of sub-pixel regions. That is, a column of pixel driving circuits 211 are electrically connected to the first power supply signal line Vdd. The first power supply signal line Vdd may be electrically connected to the second plate Cst2 of the capacitor C and the first electrode of the fifth transistor T5 through respective via holes. In addition, jumper wires Dtb are disposed in the first source-drain metal layer SD1, and a jumper wire Dtb is disposed in a sub-pixel region 330.

For example, referring to FIGS. 19B and 19C, second sub-lines 322 each extending in the second direction X are disposed in the second source-drain metal layer SD2, and the second sub-lines 322 are sequentially arranged in the first direction Y. Main lines Dta are also disposed in the second source-drain metal layer SD2; a separation gap is provided between two main lines Dta that are adjacent in the first direction Y, and a second sub-line 322 may pass through the separation gap.

Referring to FIGS. 19C and 19D, the main lines Dta and the jumper wires Dtb are alternately arranged in the first direction Y, and a main line Dta may be connected to a jumper wire Dtb through a via hole.

Next, the first source-drain metal layer SD1 and the second source-drain metal layer SD2 that are in the second wiring region 360 will be described.

For example, in the second wiring region 360, the first source-drain metal layer SD1 includes first power supply signal lines Vdd, and a layout of the first power supply signal lines Vdd is the same as a layout of the first power supply signal lines Vdd in the first wiring region 350, which may refer to FIG. 19A and will not be repeated here. Here, it will be noted that, in some embodiments, there is no jumper wire Dtb formed in the second wiring region 360. In some other embodiments, there may be jumper wires Dtb formed in the second wiring region 360. That is, a layout, located in the second wiring region 360, of the first source-drain metal layer SD1 is the same as a layout, located in the first wiring region 350, of the first source-drain metal layer SD1.

In some embodiments, referring to FIG. 18A, the active film layer 380 is disposed between the jumper wires Dtb and the substrate 310, and a jumper wire Dtb is connected to the active film layer 380 through a via hole.

In some embodiments, referring to FIG. 18A, a jumper wire Dtb has an extension portion Dtb1, and an end of the extension portion Dtb1 is connected to the active film layer 380 through a via hole.

In some examples, referring to FIG. 18A, the jumper wire Dtb further includes a main portion Dtb2; an end of the main portion Dtb2 is connected to another end of the extension portion Dtb1; two ends of the main portion Dtb2 are electrically connected to two main lines Dta through via holes, respectively; the end of the extension portion Dtb1 away from the main portion Dtb2 is electrically connected to the first electrode region of the fourth transistor T4 (which is not shown in FIG. 18A and may refer to the fourth transistor T4 in FIG. 14) through a via hole.

In some examples, referring to FIG. 19C, an orthographic projection of the extension portion Dtb1 on the substrate 310 at least partially coincide with an orthographic projection of a main line Dta on the substrate 310. In this case, the extension portion Dtb1 is at least partially located within a range where the main line Dta located, so that the extension portion Dtb1 may not cause additional metal blocking. As a result, a light transmittance of the display panel 200 is ensured, so that the display panel 200 may support an under-screen fingerprint technology.

Referring to FIGS. 20A, 20B and 20C, the second source-drain metal layer SD2 includes first sub-lines 321; each column of sub-pixel regions correspond to two first sub-lines 321, and an orthographic projection of a first first sub-line 321A on the substrate 310 is located between an orthographic projection of a data line Dt on the substrate 310 and an orthographic projection of a first power supply signal line Vdd on the substrate 310.

Other than the scheme in which the second sub-lines 322 and the main lines Dta are disposed in the second source-drain metal layer SD2, in some embodiments, the second sub-line 322 is located in a layer different from a layer where the main structures of the data lines Dt are located.

For example, the second sub-line 322 may be disposed in any one of the first gate metal layer Gate1 and the second gate metal layer Gate2. The second sub-line 322 may be electrically connected to the main structures of the data lines Dt through respective via holes.

In some embodiments, the array substrate 300 further includes at least one gate metal layer located on the first side of the substrate 310, a first source-drain metal layer SD1 located on a side of the at least one gate metal layer away from the substrate 310 and a second source-drain metal layer SD2 located on a side of the first source-drain metal layer SD1 away from the substrate 310. As shown in FIG. 24, the second sub-line 322 is disposed in any one of the gate metal layer, the first power supply signal lines Vdd are disposed in the first source-drain metal layer SD1, and the first sub-line 321 (not shown in FIG. 24) and the main structures of the data lines Dt are disposed in the second source-drain metal layer SD2.

For example, the at least one gate metal layer includes the first gate metal layer Gate1 and the second gate metal layer Gate2, and the second sub-lines 322 may be disposed in the first gate metal layer Gate1 or the second gate metal layer Gate2. In this case, the second sub-lines 322 and one of the first gate metal layer Gate1 and the second gate metal layer Gate2 may be manufactured during a same process, which makes it possible to use a same mask. As a result, there is no need to provide additional mask for providing the second sub-lines 322, so that the cost is saved.

The first sub-lines 321 and the main structures of the data lines Dt are disposed in the second source-drain metal layer SD2. In this case, the main structures of the data lines Dt may be each a complete data line Dt, the second sub-lines 322 are located in the layer different from the layer where the data lines Dt are located, so that the second sub-lines 322 are insulated from the data lines Dt through an insulating layer between the film layers.

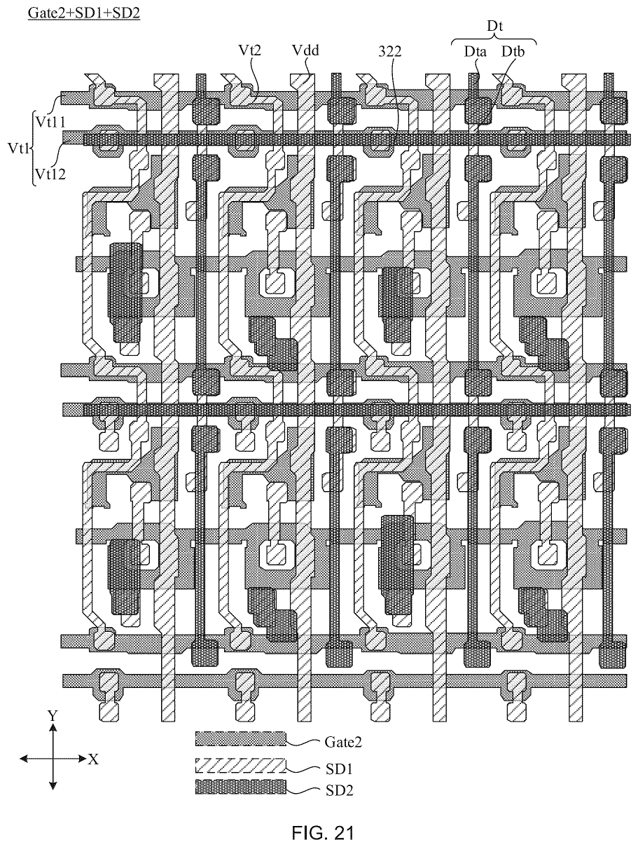

In some embodiments, referring to FIG. 21, the array substrate 300 further includes a plurality of first initial signal lines Vt1 located on the first side of the substrate 310 and located in the display area AA. The plurality of first initial signal lines Vt1 each extend in the second direction X, and the plurality of first initial signal lines Vt1 are located in a layer different from the layer in which the second sub-lines 322 are located. Referring to FIG. 21, an orthographic projection, on the substrate 310, of a first initial signal line Vt1 corresponding to a row of sub-pixel regions at least partially overlaps with an orthographic projection, on the substrate 310, of a second sub-line 322 passing through the row of sub-pixel regions.

The first initial signal line Vt1 at least partially overlaps with the second sub-line 322, which may cause a layout of the signal lines in the array substrate 300 to be compact, so as to reduce the area of the sub-pixel. As a result, the pixels per inch (PPI) of the display panel is improved. In addition, the second sub-line 322 overlaps with the first initial signal line Vt1, and there is no crosstalk created between the two, so that an accuracy of a transmission of a data signal on the second sub-line 322 is ensured. Moreover, the second sub-line 322 overlaps with the first initial signal line Vt1, which may not cause additional metal blocking, so that the light transmittance of the display panel 200 is ensured. As a result, the display panel 200 may support the under-screen fingerprint technology.

For example, a row of pixel driving circuits 211 may be electrically connected to two first initial signal lines Vt1, and the two first initial signal lines Vt1 electrically connected to the row of pixel driving circuits 211 are a first initial signal sub-line Vt11 and a second initial signal sub-line Vt12. Referring to FIG. 17, the first initial signal sub-line Vt11 and the second initial signal sub-line Vt12 are located on two sides, in the first direction Y, of the second plate Cst2 of the capacitor C.

Referring to FIG. 21, an orthographic projection, on the substrate 310, of a second sub-line 322 to which a row of sub-pixel regions correspond may at least partially overlap with an orthographic projection, on the substrate 310, of a second initial signal sub-line Vt12 to which the row of sub-pixel regions correspond. In some examples, the orthographic projection of the second sub-line 322 on the substrate 310 may be completely located within the orthographic projection of the second initial signal sub-line Vt12 on the substrate 310. In some other examples, a portion of the orthographic projection of the second sub-line 322 on the substrate 310 may be located within the orthographic projection of the second initial signal sub-line Vt12 on the substrate 310, and the other portion of the orthographic projection of the second sub-line 322 on the substrate 310 may be located outside the orthographic projection of the second initial signal sub-line Vt12 on the substrate 310.

In some embodiments, referring to FIG. 19A, the array substrate 300 further includes a plurality of second initial signal lines Vt2, and the plurality of second initial signal lines Vt2 are located on the first side of the substrate 310 and located in the display area AA. The plurality of second initial signal lines Vt2 each extend in the first direction Y. The plurality of second initial signal lines Vt2 are located in a layer different from the layer in which the plurality of first initial signal lines Vt1 are located, and the plurality of second initial signal lines Vt2 are electrically connected to the plurality of first initial signal lines Vt1 through via holes.

In some examples, in a case where the two first initial signal lines Vt1 electrically connected to the row of pixel driving circuits 211 are the first initial signal sub-line Vt11 and the second initial signal sub-line Vt12, referring to FIG. 21, a second initial signal line Vt2 may be electrically connected to the first initial signal sub-line Vt11 through a via hole, and the second initial signal line Vt2 and the first initial signal sub-line Vt11 transmit an initial signal together, so as to reduce a voltage drop of the initial signal line Vt during a transmission.

In some examples, the second initial signal line Vt2 may be located in the first source-drain metal layer SD1, and the first initial signal sub-line Vt11 and the second initial signal sub-line Vt12 are both located in the second source-drain metal layer SD2.

In some embodiments, referring to FIG. 20B, an orthographic projection, on the substrate 310, of a second initial signal line Vt2 passing through a column of sub-pixel regions at least partially overlaps with an orthographic projection, on the substrate 310, of a first sub-line 321 passing through the column of sub-pixel regions.

For example, the second source-drain metal layer SD2 includes the first sub-lines 321, a column of sub-pixel regions correspond to two first sub-lines 321, and the two first sub-lines 321 are the first first sub-line 321A and the second first sub-line 321B. Referring to FIG. 20B, the second initial signal line Vt2 at least partially overlaps with the second first sub-line 321B, which may cause the layout of the signal lines in the array substrate 300 to be compact. In addition, the second first sub-line 321B overlaps with the second initial signal line Vt2, and there is no crosstalk created between the two, so that the accuracy of the transmission of the data signal on the second sub-line 322 is ensured. Moreover, the second initial signal line Vt2 overlaps with the second first sub-line 321B, which may not cause additional metal blocking, so that the light transmittance of the display panel 200 is ensured. As a result, the display panel 200 may support the under-screen fingerprint technology.

The orthographic projection, on the substrate 310, of the first sub-line 321 (i.e., the second first sub-line 321B) at least partially overlaps with the orthographic projection, on the substrate 310, of the second initial signal line Vt2 corresponding to the column of sub-pixel regions. In some examples, the orthographic projection of the second first sub-line 321B on the substrate 310 may completely overlap with the orthographic projection of the second initial signal line Vt2 on the substrate 310. In some other examples, a portion of the orthographic projection of the second first sub-line 321B on the substrate 310 may be located within the orthographic projection of the second initial signal line Vt2 on the substrate 310, and the other portion of the orthographic projection of the second first sub-line 321B on the substrate 310 may be located outside the orthographic projection of the second initial signal line Vt2 on the substrate 310.

In some examples, referring to FIGS. 19A and 19C, the second initial signal lines Vt2 and the jumper wires Dtb are located in the same layer, and a second initial signal line Vt2 is located between a jumper wire Dtb and a first power supply signal line Vdd; the second initial signal line Vt2 has an avoidance portion Vt20, bent towards a side where the first power supply signal line Vdd is located, formed therein, and at least a portion of the jumper wire Dtb is located within an avoidance space defined by the avoidance portion Vt20.

In some examples, the second initial signal lines Vt2 and the jumper wires Dtb may be disposed in the second source-drain metal layer SD2. As for a second initial signal line Vt2, a jumper wire Dtb and a first power supply signal line Vdd that correspond to a same column of sub-pixel regions, the second initial signal line Vt2 is located between the jumper wire Dtb and the first power supply signal line Vdd.

At least a portion of the jumper wire Dtb is located within the avoidance space defined by the avoidance portion Vt20. In some examples, a portion of the jumper wire Dtb is located within the avoidance space. In some other examples, the entire jumper wire Dtb is located within the avoidance space.

In some examples, as shown in FIG. 19A, the second initial signal line Vt2 includes first lines Vt21 and avoidance portions Vt20 that are alternately arranged in the first direction Y, and the avoidance portion Vt20 may avoid the jumper wire Dtb also located in the first source-drain metal layer SD1. The avoidance portion Vt20 and the jumper wire Dtb that correspond to the same column of sub-pixel regions may be arranged in the second direction X.

In some examples, referring to FIG. 19A, the avoidance portion Vt20 includes a second line Vt22 and two third lines Vt23, two third lines Vt23 and the second line Vt22 define an avoidance region; the first line Vt21 and the second line Vt22 are alternately arranged in the first direction Y. As for the second initial signal line Vt2, the jumper wires Dtb and the first power supply signal line Vdd that correspond to the same column of sub-pixel regions, a distance between the first line Vt21 and the first power supply signal line Vdd is greater than a distance between the second line Vt22 and the first power supply signal line Vdd. The first line Vt21 and the second line Vt22 that are adjacent to each other are electrically connected via a third line Vt23, the first line Vt21 and the second line Vt22 each extend in the first direction Y, and the third line Vt23 substantially extends in the second direction X.

Some embodiments of the present disclosure provide an array substrate 300 (as shown in FIGS. 2A and 2B) including a substrate 310, a plurality of first power supply signal lines Vdd, a plurality of data lines Dt and a plurality of fan-out lines 320.

The substrate 310 has a display area AA and a peripheral area BB. The plurality of first power supply signal lines Vdd are located on a first side 3101 (as shown in FIG. 1E) of the substrate 310 and located in the display area AA.

The plurality of first power supply signal lines Vdd each extend in the first direction Y and are sequentially arranged in the second direction X. The second direction X intersects the first direction Y, and the second direction X and the first direction Y are both parallel to the substrate 310. The plurality of data lines Dt are located on the first side of the substrate 310 and located in the display area AA. The plurality of data lines Dt each extend in the first direction Y and are sequentially arranged in the second direction X. A data line Dt is adjacent to a first power supply signal line Vdd.

The plurality of fan-out lines 320 are located on the first side of the substrate 310. Referring to FIGS. 2A and 2B, a fan-out line 320 includes a first sub-line 321 and a second sub-line 322. The first sub-line 321 extends in the first direction Y and extends from the peripheral area BB to the display area AA. The second sub-line 322 extends in the second direction X and is located in the display area AA. An end of the second sub-line 322 is electrically connected to the first sub-line 321, another end of the second sub-line 322 is electrically connected to a data line Dt of the plurality of data lines Dt, and the second sub-line 322 is insulated from the remaining data lines Dt of the plurality of data lines Dt. As shown in FIGS. 3A and 3B, a main structure of the data line Dt is located on the side of the first power supply signal lines Vdd away from the substrate 310; the first sub-lines 321 and the main structures of the data lines Dt are disposed in the same layer.

The array substrate 300 has pixel driving circuits 211 in a plurality of rows and a plurality of columns; an orthographic projection, on the substrate 310, of a first sub-line 321 passing through a column of pixel driving circuits is located between an orthographic projection, on the substrate 310, of a first power supply signal line Vdd electrically connected to the column of pixel driving circuits and an orthographic projection, on the substrate 310, of a data line Dt electrically connected to the column of pixel driving circuits.

The description that a first sub-line 321 passes through a column of pixel driving circuits refers to that an orthographic projection of the first sub-line 321 on the substrate 310 overlaps with orthographic projections, on the substrate 310, of some or all of pixel driving circuits 211 in the column of pixel driving circuits.

The pixel driving circuits 211 in the plurality of rows and the plurality of columns are disposed in the display area AA of the substrate 310. Pixel driving circuits 211 in a column are sequentially arranged in the first direction Y. Pixel driving circuits 211 in a row are sequentially arranged in the second direction X.

A first power supply signal line Vdd is electrically connected to a column of pixel driving circuits, so that the first power supply signal line Vdd may provide a first power supply signal for the column of pixel driving circuits. A data line Dt is electrically connected to a column of pixel driving circuits, so that the data line Dt may provide data signals for respective pixel driving circuits in the column.

In the array substrate 300 provided in some embodiments of the present disclosure, the first sub-lines 321 and the main structures of the data lines Dt are disposed in the same layer, which makes it possible to manufacture the main structures of the data lines Dt and the first sub-line 321 by using the same mask, so that there is no need to provide additional mask for manufacturing the first sub-line 321. Therefore, a relatively small number of masks may be used during the process of manufacturing the display panel 200, thereby saving the cost.

Some embodiments of the present disclosure provide a display panel 200. Referring to FIG. 1C, the display panel 200 includes the array substrate 300 provide in the above embodiments, a light-emitting device layer 400 and an encapsulation layer 500. The light-emitting device layer 400 is located on a side of the array substrate 300 away from the substrate 310; the encapsulation layer 500 is located on a side of the light-emitting device layer 400 away from the array substrate 300.

A bottom layer of the array substrate 300 is the substrate 310, and a top layer of the array substrate 300 is the second source-drain metal layer SD2. In some embodiments, a planarization layer is provided on a side of the second source-drain metal layer SD2 away from the substrate 310, and the light-emitting device layer 400 is disposed on the planarization layer.

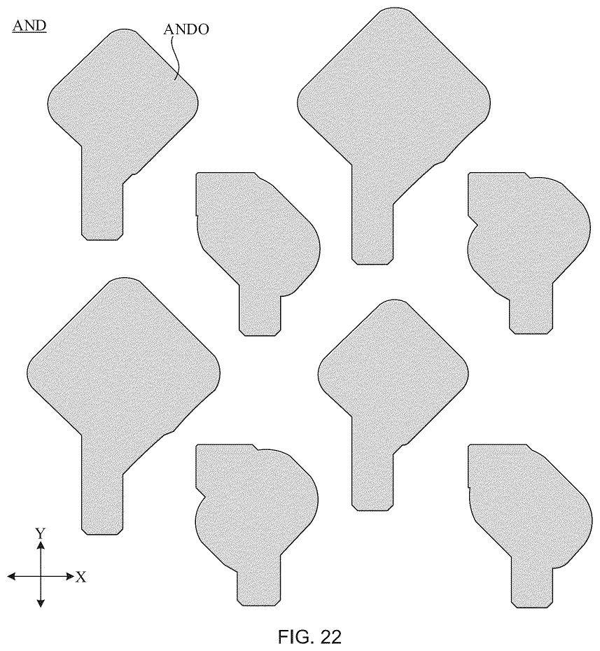

The light-emitting device layer 400 includes a plurality of light-emitting devices OLED. The light-emitting device layer 400 includes an anode layer AND, a light-emitting layer and a cathode layer that are sequentially arranged on the planarization layer. Referring to FIG. 22, the anode layer AND includes a plurality of anode patterns ANDO each used for forming an anode of a light-emitting device OLED.

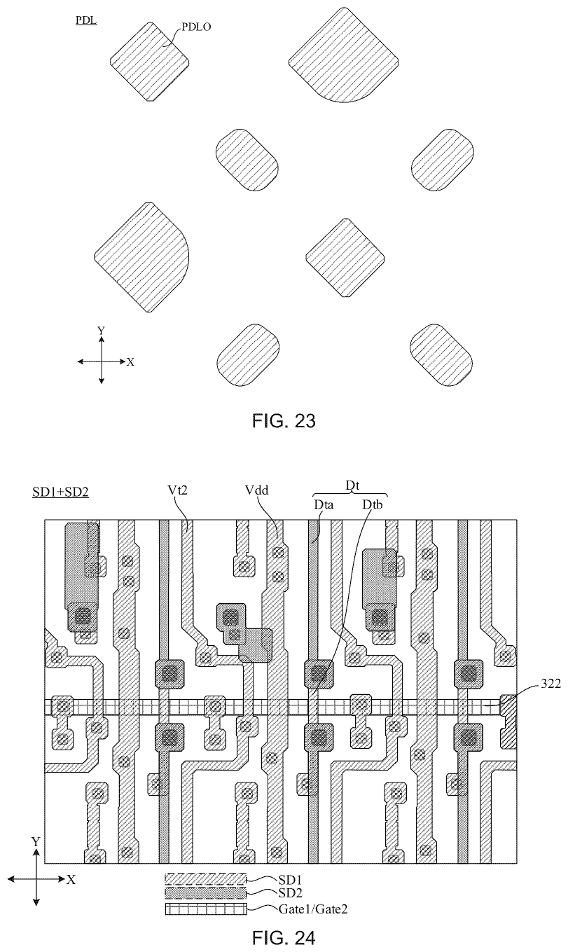

Referring to FIG. 23, the anode layer AND is provided with a pixel definition layer PDL formed thereon; the pixel definition layer PDL is provided with a plurality of pixel openings PDLO formed therein, and the light-emitting layer may be disposed in the pixel openings PDLO.

The encapsulation layer 500 covers the light-emitting devices OLED and encapsulate the light-emitting devices OLED, so as to prevent a lifetime of the OLED display panel 200 from being shortened due to a fact that moisture and oxygen in the external environment enter the display panel 200 and damage organic materials in the light-emitting devices OLED.

A display apparatus 100 provided in some embodiments of the present disclosure includes the display panel 200 provided in any one of the above embodiments. Thus, the display apparatus 100 provided in the embodiments of the present disclosure has all beneficial effects of the display panel 200 provided in any one of the above embodiments, which will not be repeated here.

Referring to FIG. 4A, the display panel 200 includes a display area AA and a peripheral area BB, and the peripheral area BB of the display panel 200 includes a lead-out region B10 and a bonding region B6 that are located on a side of the display area AA, and the bonding region B6 is located on a side of the lead-out region B10 away from the display area AA. It will be noted that the display panel 200 includes the array substrate 300, the array substrate 300 includes the display area AA and the peripheral area BB, the display area AA of the display panel 200 and the display area AA of the array substrate 300 are a same region, the peripheral area BB of the display panel 200 and the peripheral area BB of the array substrate 300 are a same region.

In some embodiments, the lead-out region B10 may include the bending region B2, the second fan-out region B3 and the test circuit region B4 that are provided in the above embodiments. Functions of the bending region B2, the second fan-out region B3 and the test circuit region B4 are described above, which will not be repeated here.

In some embodiments, the display panel 200 further includes a flexible circuit board and a main control circuit board; an end of the flexible circuit board is bonded in the bonding region B6, and the main control circuit board is electrically connected to another end of the flexible circuit board.

In some examples, referring to FIG. 4A, the lead-out region B10 includes the bending region B2, the second fan-out region B3 and the test circuit region B4. The display panel 200 further includes a chip region B5, the lead-out region B10 is located between the chip region B5 and the display area AA, and the bonding region B6 is located on a side of the chip region B5 away from the lead-out region B10. The first sub-line 321 may pass through the lead-out region B10 and extend the chip region B5, and a driver IC is bonded, in the chip region B5, to the first sub-line 321. The first power supply signal line Vdd extends to the bonding region B6 through the lead-out region B10 and the chip region B5. The bonding region B6 is provided with a plurality of pins therein; lead-out portions of the first power supply signal lines Vdd may be gathered in the second fan-out region B3 of the lead-out region B10, and the lead-out portions of the first power supply signal lines Vdd may be electrically connected to part of the pins in the bonding region B6 passing through the lead-out region B10 and the chip region B5. Thus, the main control circuit board may transmit, through the part of the pins, the first power supply signal to the lead-out portions of the first power supply signal lines Vdd through the flexible circuit board, so that the first power supply signal is transmitted to the first power supply signal lines Vdd.

In some other examples, referring to FIG. 4B, the lead-out region B10 does not include the bending region, and there is no chip region provided on the side of the lead-out region B10 away from the display area AA. In this case, the lead-out region B10 includes the second fan-out region B3 and the test circuit region B4, and the bonding region B6 is disposed on the side of the lead-out region B10 away from the display area AA. In this case, the first sub-line 321 may extend to the bonding region B6 through the lead-out region B10 and be electrically connected to the plurality of pins in the bonding region B6. The driver IC is bonded to the flexible circuit board, and the flexible circuit board is bonded to the plurality of pins in the bonding region B6. In these examples, the flexible circuit board is folded onto a back surface of the display panel 200.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. An array substrate, comprising:
a substrate having a display area and a peripheral area;
a plurality of first power supply signal lines located on a first side of the substrate and located in the display area; wherein the plurality of first power supply signal lines each extend in a first direction and are sequentially arranged in a second direction; the second direction intersects the first direction, and the second direction and the first direction are both parallel to the substrate;
a plurality of data lines located on the first side of the substrate and located in the display area; wherein the plurality of data lines each extend in the first direction and are sequentially arranged in the second direction; a data line is adjacent to a first power supply signal line; and
a plurality of fan-out lines located on the first side of the substrate; wherein the plurality of fan-out lines each include a first sub-line and a second sub-line; the first sub-line extends in the first direction and extends from the peripheral area to the display area; the second sub-line extends in the second direction and is located in the display area; an end of the second sub-line is electrically connected to the first sub-line, another end of the second sub-line is electrically connected to a single data line of the plurality of data lines, and the second sub-line is insulated from remaining data lines of the plurality of data lines; wherein
main structures of the plurality of data lines are located on a side of the first power supply signal lines away from the substrate, and the first sub-line and the main structures of the plurality of data lines are disposed in a same layer;
the display area has sub-pixel regions in a plurality of rows and a plurality of columns; an orthographic projection, on the substrate, of a first sub-line passing through a column of sub-pixel regions is substantially located between an orthographic projection, on the substrate, of a first power supply signal line passing through the column of sub-pixel regions and an orthographic projection, on the substrate, of a data line passing through the column of sub-pixel regions.

2. The array substrate according to claim 1, wherein
the peripheral area includes a lead-out region located on a side of the display area; the first sub-line extends from the lead-out region to the display area, and a length of at least one first sub-line is not greater than half a dimension of the display area in the first direction; or
the peripheral area includes the lead-out region located on the side of the display area; the first sub-line extends from the lead-out region to the display area, and the length of the at least one first sub-line is not greater than half the dimension of the display area in the first direction; a direction from a center line, in the second direction, of the display area to any side of the display area in the second direction is a first setting direction; lengths of portions, located in the display area, of first sub-lines of all first sub-lines included in the plurality of fan-out lines sequentially decrease in the first setting direction.

3. (canceled)

4. The array substrate according to claim 1, wherein
the main structures of the plurality of data lines each include a plurality of main lines;
at least part of the plurality of data lines each further include at least one jumper wire, and the at least one jumper wire and the first power supply signal lines are disposed in another same layer; in a same data line, at least one jumper wire and main lines are alternately electrically connected to one other through via holes;
the second sub-line and the plurality of main lines are arranged in the same layer, and each of at least one second sub-line crosses a jumper wire of at least one data line.

5. The array substrate according to claim 4, further comprising:
an active film layer disposed between the at least one jumper wire and the substrate; wherein
a jumper wire has an extension portion, and an end of the extension portion is connected to the active film layer through a via hole.

6. The array substrate according to claim 4, wherein
a minimum closed graphic region where all second sub-lines, located on a same side of a center line of the display area in the second direction, are located is a first wiring region; at least a portion, located within the first wiring region, of each of data lines passing through the first wiring region is provided with a jumper wire.

7. The array substrate according to claim 4, wherein
a direction from a center line, in the second direction, of the display area to any side of the display area in the second direction is a first setting direction;
numbers of jumper wires respectively included in data lines firstly increase and then decrease in the first setting direction.

8. The array substrate according to claim 6, wherein
of all the data lines passing through the first wiring region, a data line of which a portion located within the first wiring region has a greatest number of jumper wires is a first-type data line, and data lines other than the first-type data line are second-type data lines; a portion, located outside the first wiring region, of each of all the second-type data lines is provided with a jumper wire; a number of jumper wires included in each of all the second-type data lines is equal to a number of jumper wires included in the first-type data line; or
of all the data lines passing through the first wiring region, the data line of which the portion located within the first wiring region has the greatest number of jumper wires is the first-type data line, and the data lines other than the first-type data line are the second-type data lines; the portion, located outside the first wiring region, of each of all the second-type data lines is provided with the jumper wire; the number of jumper wires included in each of all the second-type data lines is equal to the number of jumper wires included in the first-type data line; an end of the first sub-line connected to the second sub-line is a first end, and another end of the first sub-line is a second end; a direction from the second end to the first end is a second setting direction; of each of all the second-type data lines, the jumper wire located within the first wiring region and the jumper wire located outside the first wiring region are arranged in the second setting direction.

9. (canceled)

10. The array substrate according to claim 6, wherein
a portion, located outside the first wiring region, of each of all the data lines passing through the first wiring region is provided with a jumper wire; a number of jumper wires included in each data line is equal; jumper wires included in all the data lines passing through the first wiring region are arranged in rows in the first direction.

11. The array substrate according to claim 4, comprising:
a first source-drain metal layer located on the first side of the substrate; and
a second source-drain metal layer located on a side of the first source-drain metal layer away from the substrate;
wherein the first power supply signal lines and the at least one jumper wire are located in the first source-drain metal layer, and the first sub-line, the second sub-line and the plurality of main lines are located in the second source-drain metal layer.

12. The array substrate according to claim 1, wherein
the second sub-line is located in a layer different from the layer in which the main structures of the plurality of data lines are located.

13. The array substrate according to claim 12, comprising:
at least one gate metal layer located on the first side of the substrate;
a first source-drain metal layer located on a side of the at least one gate metal layer away from the substrate; and
a second source-drain metal layer located on a side of the first source-drain metal layer away from the substrate;
wherein the second sub-line is disposed in any gate metal layer, the first power supply signal lines are disposed in the first source-drain metal layer, and the first sub-line and the main structures of the plurality of data lines are disposed in the second source-drain metal layer.

14. The array substrate according to claim 4, further comprising:
a plurality of first initial signal lines located on the first side of the substrate and located in the display area; the plurality of first initial signal lines each extending in the second direction; wherein
the plurality of first initial signal lines are located in a layer different from a layer in which the second sub-line is located; an orthographic projection, on the substrate, of a first initial signal line passing through a row of sub-pixel regions at least partially overlaps with an orthographic projection, on the substrate, of a second sub-line passing through the row of sub-pixel regions.

15. The array substrate according to claim 14, further comprising:
a plurality of second initial signal lines located on the first side of the substrate and located in the display area; the plurality of second initial signal lines each extending in the first direction; wherein
the plurality of second initial signal lines are located in a layer different from the layer in which the plurality of first initial signal lines are located, and the plurality of second initial signal lines are electrically connected to the plurality of first initial signal lines through another via holes; an orthographic projection, on the substrate, of another first sub-line passing through the column of sub-pixel regions at least partially overlaps with an orthographic projection, on the substrate, of a second initial signal line passing through the column of sub-pixel regions; or
the plurality of second initial signal lines are located in the layer different from the layer in which the plurality of first initial signal lines are located, and the plurality of second initial signal lines are electrically connected to the plurality of first initial signal lines through the another via holes; the orthographic projection, on the substrate, of the another first sub-line passing through the column of sub-pixel regions at least partially overlaps with the orthographic projection, on the substrate, of the second initial signal line passing through the column of sub-pixel regions; the second initial signal lines and the at least one jumper wire are located in the another same layer, and a second initial signal line is located between a jumper wire and a first power supply signal line; the second initial signal line has an avoidance portion bent towards a side where the first power supply signal line is located, and at least a portion of the jumper wire is located within an avoidance space defined by the avoidance portion.

16. (canceled)

17. An array substrate, comprising:
a substrate having a display area and a peripheral area;
a plurality of first power supply signal lines located on a first side of the substrate and located in the display area; wherein the plurality of first power supply signal lines each extend in a first direction and are sequentially arranged in a second direction; the second direction intersects the first direction, and the second direction and the first direction are both parallel to the substrate;
a plurality of data lines located on the first side of the substrate and located in the display area; wherein the plurality of data lines each extend in the first direction and are sequentially arranged in the second direction; a data line is adjacent to a first power supply signal line; and
a plurality of fan-out lines located on the first side of the substrate; wherein a fan-out line includes a first sub-line and a second sub-line; the first sub-line extends in the first direction and extends from the peripheral area to the display area; the second sub-line extends in the second direction and is located in the display area; an end of the second sub-line is electrically connected to the first sub-line, another end of the second sub-line is electrically connected to a single data line of the plurality of data lines, and the second sub-line is insulated from remaining data lines of the plurality of data lines; wherein
main structures of the data lines are located on a side of the first power supply signal lines away from the substrate, and the first sub-line and the main structures of the data lines are disposed in a same layer;
the array substrate has pixel driving circuits in a plurality of rows and a plurality of columns; an orthographic projection, on the substrate, of the first sub-line passing through a column of pixel driving circuits is located between an orthographic projection, on the substrate, of a first power supply signal line passing through the column of pixel driving circuits and an orthographic projection, on the substrate, of a data line passing through the column of pixel driving circuits.

18. A display panel, comprising:
the array substrate according to claim 1;
a light-emitting device layer located on a side of the array substrate; and
an encapsulation layer located on a side of the light-emitting device layer away from the array substrate.

19. A display apparatus, comprising:
the display panel according to claim 18; the peripheral area of the display panel including a lead-out region and a bonding region that are located on a side of the display area, and the bonding region being located on a side of the lead-out region away from the display area;
a flexible circuit board of which an end is bonded in the bonding region; and
a main control circuit board electrically connected to another end of the flexible circuit board.

20. The array substrate according to claim 12, further comprising:
a plurality of first initial signal lines located on the first side of the substrate and located in the display area; the plurality of first initial signal lines each extending in the second direction; wherein
the plurality of first initial signal lines are located in a layer different from the layer in which the second sub-line is located; an orthographic projection, on the substrate, of a first initial signal line passing through a row of sub-pixel regions at least partially overlaps with an orthographic projection, on the substrate, of a second sub-line passing through the row of sub-pixel regions.

21. The array substrate according to claim 20, further comprising:
a plurality of second initial signal lines located on the first side of the substrate and located in the display area; the plurality of second initial signal lines each extending in the first direction; wherein
the plurality of second initial signal lines are located in a layer different from the layer in which the plurality of first initial signal lines are located, and the plurality of second initial signal lines are electrically connected to the plurality of first initial signal lines through via holes; an orthographic projection, on the substrate, of another first sub-line passing through the column of sub-pixel regions at least partially overlaps with an orthographic projection, on the substrate, of a second initial signal line passing through the column of sub-pixel regions.

22. A display panel, comprising:
the array substrate according to claim 17;
a light-emitting device layer located on a side of the array substrate; and
an encapsulation layer located on a side of the light-emitting device layer away from the array substrate.

23. A display apparatus, comprising:
the display panel according to claim 22; the peripheral area of the display panel including a lead-out region and a bonding region that are located on a side of the display area, and the bonding region being located on a side of the lead-out region away from the display area;
a flexible circuit board of which an end is bonded in the bonding region; and
a main control circuit board electrically connected to another end of the flexible circuit board.
